(19) United States
(12) Patent Application Publication
(10) Pub. No.: US 2013/0025914 A1
(43) Pub. Date: Jan. 31, 2013

(54) WIRING BOARD AND METHOD FOR MANUFACTURING THE SAME

(71) Applicants: Nobuyuki Naganuma, Ogaki-shi (JP); Michimasa Takahashi, Ogaki-shi (JP)

(72) Inventors: Nobuyuki Naganuma, Ogaki-shi (JP); Michimasa Takahashi, Ogaki-shi (JP)

(73) Assignee: IBIDEN Co., Ltd., Ogaki-shi (JP)

(21) Appl. No.: 13/538,095

(22) Filed: Jun. 29, 2012

Related U.S. Application Data
(60) Provisional application No. 61/511,342, filed on Jul. 25, 2011.

(51) Int. Cl. H05K 1/14; H05K 3/36

(52) U.S. Cl. 174/251; 29/830

(57) ABSTRACT

A wiring board has wiring board has a first rigid wiring board having an accommodation portion and a conductor, a second rigid wiring board accommodated in the accommodation portion and having a conductor electrically connected to the conductor in the first rigid wiring board, and an insulation layer formed over the first rigid wiring board and the second rigid wiring board. The first rigid wiring board has a wall surface defining the accommodation portion and having a concavo-convex shaped portion, and the second rigid wiring board has a side surface facing against the wall surface of the first rigid wiring board and having a concavo-convex shaped portion such that the concavo-convex shaped portion of the side surface of the second rigid wiring board engages with the concavo-convex shaped portion of the wall surface of the first rigid wiring board.

### CROSS-REFERENCE TO RELATED APPLICATIONS

The present application is based on and claims the benefit of priority to U.S. Application No. 61/511,342, filed Jul. 25, 2011, the entire contents of which are incorporated herein by reference.

### BACKGROUND OF THE INVENTION

1. Field of the Invention

The present invention relates to a wiring board and its manufacturing method.

2. Discussion of the Background

In Taiwanese Patent Publication No. 200847363, a wiring board is described where a second wiring board is accommodated in a hole formed in a first wiring board, and wiring in the first wiring board and wiring in the second wiring board are electrically connected. The entire contents of Taiwanese Patent Publication No. 200847363 are incorporated in this application.

### SUMMARY OF THE INVENTION

According to one aspect of the present invention, a wiring board has a first rigid wiring board having an accommodation portion and a conductor, a second rigid wiring board accommodated in the accommodation portion and having a conductor electrically connected to the conductor in the first rigid wiring board, and an insulation layer formed over the first rigid wiring board and the second rigid wiring board. The first rigid wiring board has a wall surface defining the accommodation portion and having a concavo-convex shaped portion, and the second rigid wiring board has a side surface facing against the wall surface of the first rigid wiring board and having a concavo-convex shaped portion such that the concavo-convex shaped portion of the side surface of the second rigid wiring board engages with the concavo-convex shaped portion of the wall surface of the first rigid wiring board.

According to another aspect of the present invention, a method for manufacturing a wiring board includes preparing a first rigid wiring board having an accommodation portion and a conductor, preparing a second rigid wiring board having a conductor, accommodating the second rigid wiring board in the accommodation portion of the first rigid wiring board, forming an insulation layer over the first rigid wiring board and the second rigid wiring board, and electrically connecting the conductor in the first rigid wiring board to the conductor in the second rigid wiring board. The preparing of the first rigid wiring board includes forming a wall surface which defines the accommodation portion and has a concavo-convex shaped portion, the preparing of the second rigid wiring board includes forming a side surface which faces against the wall surface of the first rigid wiring board and has a concavo-convex shaped portion such that the concavo-convex shaped portion of the side surface of the second rigid wiring board engages with the concavo-convex shaped portion of the wall surface of the first rigid wiring board, and the accommodating of the second rigid wiring board includes engaging the concavo-convex shaped portion of the side surface of the second rigid wiring board with the concavo-convex shaped portion of the wall surface of the first rigid wiring board.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view of a wiring board according to an embodiment of the present invention;

FIG. 2 is a plan view of the wiring board shown in FIG. 1;

FIG. 3 is a view showing an inner-layer structure of the wiring board according to the embodiment of the present invention;

FIG. 4 is a view showing a first rigid wiring board of the wiring board according to the embodiment of the present invention;

FIG. 5 is a view showing a second rigid wiring board of the wiring board according to the embodiment of the present invention;

FIG. 6 is, in the wiring board according to the embodiment of the present invention, a view showing a state where the second rigid wiring board is accommodated in an accommodation section of the first rigid wiring board;

FIG. 7 is, in the wiring board according to the embodiment of the present invention, a view showing a side-surface shape of the second rigid wiring board and a wall-surface shape of the accommodation section;

FIG. 8A is, in a method for manufacturing a wiring board according to the embodiment of the present invention, a view to illustrate a first step for forming a first rigid wiring board;

FIG. 8B is a view to illustrate a second step subsequent to the step in FIG. 8A;

FIG. 8C is a view to illustrate a third step subsequent to the step in FIG. 8B;

FIG. 8D is a view to illustrate a fourth step subsequent to the step in FIG. 8C;

FIG. 9 is, in the method for manufacturing a wiring board according to the embodiment of the present invention, a view showing an example in which multiple first rigid wiring boards are formed collectively;

FIG. 10A is, in the method for manufacturing a wiring board according to the embodiment of the present invention, a view to illustrate a first step for forming a second rigid wiring board;

FIG. 10B is a view to illustrate a second step subsequent to the step in FIG. 10A;

FIG. 10C is a view to illustrate a third step subsequent to the step in FIG. 10B;

FIG. 10D is a view to illustrate a fourth step subsequent to the step in FIG. 10C;

FIG. 11A is a view to illustrate a fifth step subsequent to the step in FIG. 10D;

FIG. 11B is a view to illustrate a sixth step subsequent to the step in FIG. 11A;

FIG. 11C is a view to illustrate a seventh step subsequent to the step in FIG. 11B;

FIG. 11D is a view to illustrate an eighth step subsequent to the step in FIG. 11C;

FIG. 12A is a view to illustrate a ninth step subsequent to the step in FIG. 11D;

FIG. 12B is a view to illustrate a 10th step subsequent to the step in FIG. 12A;

FIG. 12C is a view to illustrate an 11th step subsequent to the step in FIG. 12B;

FIG. 12D is a view to illustrate a 12th step subsequent to the step in FIG. 12C;

FIG. 13 is, in the method for manufacturing a wiring board according to the embodiment of the present invention, a view showing an example in which multiple second rigid wiring boards are formed collectively;

FIG. 14 is, in the method for manufacturing a wiring board according to the embodiment of the present invention, a view showing an example in which an accommodation section is formed in a first rigid wiring board using a die;

FIG. 15 is, in the method for manufacturing a wiring board according to the embodiment of the present invention, a view showing an example in which an accommodation section is formed in a first rigid wiring board using a laser;

FIG. 16 is, in the method for manufacturing a wiring board according to the embodiment of the present invention, a view showing accommodation sections formed in first rigid wiring boards;

FIG. 17A is, in the method for manufacturing a wiring board according to the embodiment of the present invention, a view to illustrate a step for positioning a second rigid wiring board in an accommodation section of a first rigid wiring board;

FIG. 17B is, in the method for manufacturing a wiring board according to the embodiment of the present invention, a view to illustrate a step for forming holes for via holes and joint conductors;

FIG. 18A is, in the method for manufacturing a wiring board according to the embodiment of the present invention, a view to illustrate a step for filling conductor in the holes for via holes and joint conductors;

FIG. 18B is, in the method for manufacturing a wiring board according to the embodiment of the present invention, a view to illustrate a step for patterning conductive layers connected to both ends of joint conductors;

FIG. 19A is, in another embodiment of the present invention, a view of a first example showing the side-surface shape of a second rigid wiring board and the wall-surface shape of an accommodation section in a first rigid wiring board;

FIG. 19B is, in yet another embodiment of the present invention, a view of a second example showing the side-surface shape of a second rigid wiring board and the wall-surface shape of an accommodation section in a first rigid wiring board;

FIG. 19C is, in yet another embodiment of the present invention, a view of a third example showing the side-surface shape of a second rigid wiring board and the wall-surface shape of an accommodation section in a first rigid wiring board;

FIG. 19D is, in yet another embodiment of the present invention, a view of a fourth example showing the side-surface shape of a second rigid wiring board and the wall-surface shape of an accommodation section in a first rigid wiring board;

FIG. 20 is, in yet another embodiment of the present invention, a view of a fifth example showing the side-surface shape of a second rigid wiring board and the wall-surface shape of an accommodation section in a first rigid wiring board;

FIG. 21A is, in yet another embodiment of the present invention, a view of a sixth example showing the side-surface shape of a second rigid wiring board and the wall-surface shape of an accommodation section in a first rigid wiring board;

FIG. 21B is, in yet another embodiment of the present invention, a view of a seventh example showing the side-surface shape of a second rigid wiring board and the wall-surface shape of an accommodation section in a first rigid wiring board;

FIG. 21C is, in yet another embodiment of the present invention, a view of an eighth example showing the side-surface shape of a second rigid wiring board and the wall-surface shape of an accommodation section in a first rigid wiring board;

FIG. 22 is, in yet another embodiment of the present invention, a view of a ninth example showing the side-surface shape of a second rigid wiring board and the wall-surface shape of an accommodation section in a first rigid wiring board;

FIG. 23 is, in yet another embodiment of the present invention, a view of a 10th example showing the side-surface shape of a second rigid wiring board and the wall-surface shape of an accommodation section in a first rigid wiring board;

FIG. 24 is, in yet another embodiment of the present invention, a view of an 11th example showing the side-surface shape of a second rigid wiring board and the wall-surface shape of an accommodation section in a first rigid wiring board;

FIG. 25 is, in yet another embodiment of the present invention, a view of a 12th example showing the side-surface shape of a second rigid wiring board and the wall-surface shape of an accommodation section in a first rigid wiring board;

FIG. 26 is, in yet another embodiment of the present invention, a view of a 13th example showing the side-surface shape of a second rigid wiring board and the wall-surface shape of an accommodation section in a first rigid wiring board;

FIG. 27 is, in yet another embodiment of the present invention, a view showing an example in which a second concavo-convex shape finer than a first concavo-convex shape is formed in the first concavo-convex shape formed on a wall surface of the accommodation section in a first rigid wiring board or on a side surface of a second rigid wiring board;

FIG. 28A is, in yet another embodiment of the present invention, a view showing an example in which a second concavo-convex shape finer than a first concavo-convex shape is formed in each concave portion and in each convex portion of the first concavo-convex shape;

FIG. 28B is, in yet another embodiment of the present invention, a view showing an example in which a second concavo-convex shape finer than a first concavo-convex shape is formed in a convex portion of the first concavo-convex shape;

FIG. 28C is, in yet another embodiment of the present invention, a view showing an example in which a second concavo-convex shape finer than a first concavo-convex shape is formed in a concave portion of the first concavo-convex shape;

FIG. 29A is, in yet another embodiment of the present invention, a view showing an example where a wall surface of an accommodation section and a side surface of a second rigid wiring board are formed in a zigzag pattern only near a corner;

FIG. 29B is, in yet another embodiment of the present invention, a view showing an example where a wall surface of an accommodation section and a side surface of a second rigid wiring board are formed in a zigzag pattern only in a region along a side;

FIG. 30 is, in yet another embodiment of the present invention, a view showing an example where multiple convex portions formed on a wall surface of an accommodation section are inserted in a concave portion formed on a side surface of a second rigid wiring board;

FIG. 31 is, in yet another embodiment of the present invention, a view showing an example of planar shapes of a second rigid wiring board and an accommodation section;

FIG. 32 is, in yet another embodiment of the present invention, a view showing an example where the density of conductive patterns in a second rigid wiring board is set higher than the density of conductive patterns in a first rigid wiring board;

FIG. 33 is, in yet another embodiment of the present invention, a view showing an example where multiple second rigid wiring boards are accommodated in an accommodation section formed in a first rigid wiring board;

FIG. 34 is, in yet another embodiment of the present invention, a view showing a wiring board having laminated sections formed by alternately laminating multiple insulation layers and multiple conductive layers on a first rigid wiring board and on a second rigid wiring board;

FIG. 35 is, in yet another embodiment of the present invention, a view showing an example where an accommodation section formed in a first rigid wiring board is a hole that does not penetrate through the first rigid wiring board; and

FIG. 36 is, in yet another embodiment of the present invention, a view showing an example where a wall surface of an accommodation section is tapered.

### DETAILED DESCRIPTION OF THE EMBODIMENTS

The embodiments will now be described with reference to the accompanying drawings, wherein like reference numerals designate corresponding or identical elements throughout the various drawings.

In the drawings, arrows (Z1, Z2) each indicate a lamination direction in a wiring board corresponding to a direction along a normal line (or a thickness direction of the wiring board) to the main surfaces (upper and lower surfaces) of the wiring board. On the other hand, arrows (X1, X2) and (Y1, Y2) each indicate a direction perpendicular to a lamination direction (or a direction to a side of each layer). The main surfaces of the wiring board are on the X-Y plane. Side surfaces of the wiring board are on the X-Z plane or the Y-Z plane. “Directly on” or “directly under” means direction Z (Z1 side or Z2 side).

In the present embodiment, a side closer to the core (substrates 100, 200) is referred to as a lower layer, and a side farther from the core as an upper layer in a lamination direction.

A conductive layer is formed with one or multiple conductive patterns. A conductive layer may include a conductive pattern that forms an electrical circuit such as wiring (including ground), a pad, a land or the like, for example, or it may include a planar conductive pattern that does not form an electrical circuit.

Opening portions include notches, cuts or the like in addition to holes and grooves. Holes are not limited to penetrating holes, and non-penetrating holes are also referred to as holes.

Among the conductors formed in opening portions, conductive film formed on inner surfaces of an opening portion (wall or bottom surface) is referred to as a conformal conductor, and conductor filled in an opening portion as a filled conductor. Also, conductor formed in a via hole (wall or bottom surface) is referred to as a via conductor, and conductor formed in a through hole (wall surface) as a through-hole conductor. A stacked-conductor structure means an assembly formed by stacking filled conductors in two or more layers.

Plating includes wet plating such as electrolytic plating as well as dry plating such as PVD (physical vapor deposition) and CVD (chemical vapor deposition).

“Accommodated in an accommodation section” includes situations in which the entire second rigid wiring board is positioned completely in an accommodation section, as well as situations in which only part of a second rigid wiring board is positioned in an accommodation section. In short, it is sufficient if at least part of a second rigid wiring board is positioned in an accommodation section.

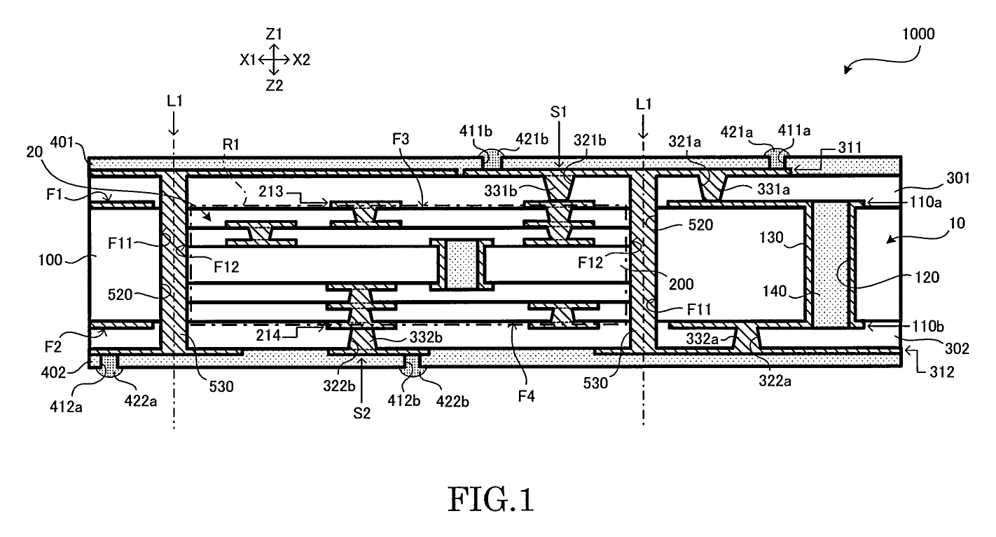

As shown in FIG. 1, wiring board 1000 of the present embodiment has wiring board 10 (first rigid wiring board), wiring board 20 (second rigid wiring board), insulation layers (301, 302), conductive layers (311, 312), via conductors (331a, 331b, 332a, 332b), through-hole conductor 530 (joint conductor), solder resists (401, 402), and external connection terminals (421a, 421b, 422a, 422b). In the following, one (Z1 side) of upper and lower surfaces (two main surfaces) of wiring board 10 is referred to as first surface (F1), and the other (Z2 side) as second surface (F2). Also, one (Z1 side) of upper and lower surfaces (two main surfaces) of wiring board 20 is referred to as third surface (F3), and the other (Z2 side) as fourth surface (F4).

Wiring board 10 has accommodation section (R1), and wiring board 20 is accommodated in accommodation section (R1) formed in wiring board 10. Conductor in wiring board 10 and conductor in wiring board 20 are electrically connected to each other. In addition, insulation layers (301, 302) are each formed on wiring board 10 and on wiring board 20. Accommodation section (R1) of the present embodiment is a penetrating hole. Wiring board 1000, wiring board 10 and wiring board 20 are each a rigid printed wiring board.

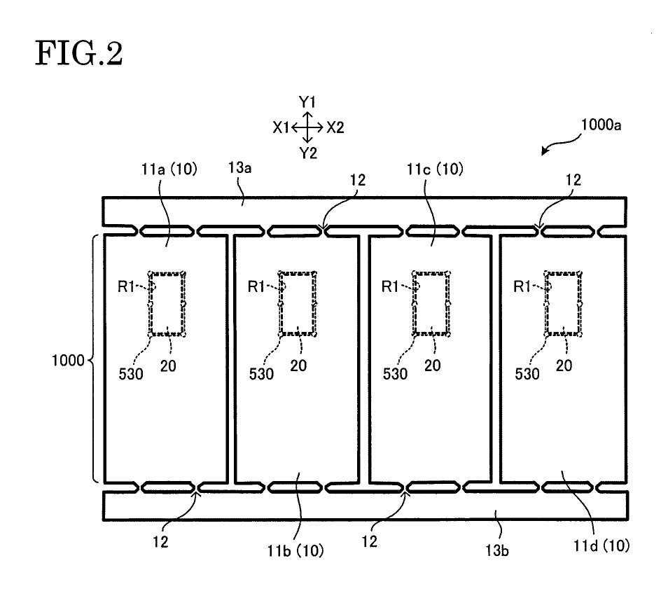

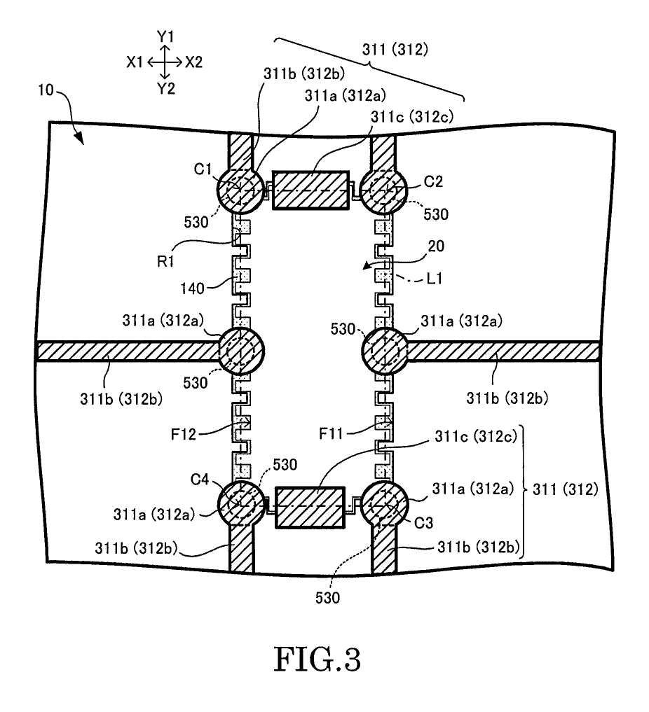

In the present embodiment, multiple wiring boards 1000 form frame unit (1000a) as shown in FIGS. 2 and 3, for example. Frame unit (1000a) is structured with frame sections (13a, 13b) and multiple wiring board sections (11a˜11d) (each corresponds to wiring board 10) formed in an integrated fashion. Wiring board sections (11a˜11d) are each connected to frame sections (13a, 13b) by bridges 12. Wiring board sections (11a˜11d) each have accommodation section (R1), and wiring board 20 is accommodated in each accommodation section (R1).

In the present embodiment, connection portions (bridges 12) between wiring board sections (11a˜11d) (wiring boards 10) and frame sections (13a, 13b) are made narrow so that they are easier to cut. Since wiring board 1000 is connected to frame sections (13a, 13b), handling of wiring board 1000 is easier. The present embodiment shows an example in which multiple wiring boards 1000 are connected to a frame. However, one wiring board 1000 may be connected to a frame.

FIG. 3 shows an inner-layer structure of wiring board 1000 according to the present embodiment. The planar shape (X-Y plane) of wiring board 20 built into wiring board 1000 is substantially rectangular, for example, as shown in FIG. 3. However, that is not the only option, and the shape of wiring board 20 may be determined freely.

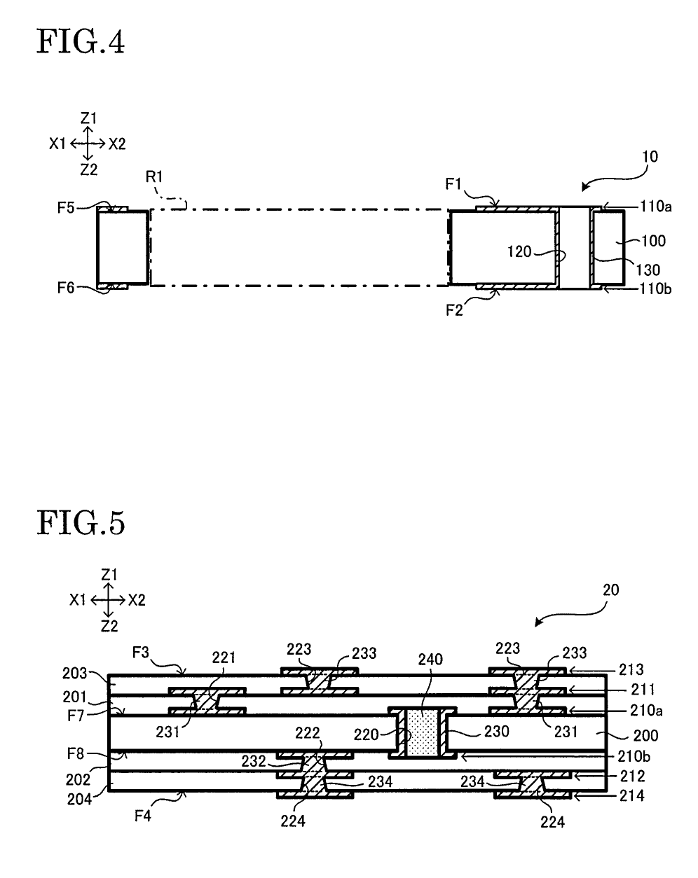

As shown in FIG. 4, wiring board 10 (first rigid wiring board) has insulative substrate 100 (the core substrate of wiring board 10) and conductive layers (110a, 110b). In the following, one (Z1 side) of upper and lower surfaces (two main surfaces) of substrate 100 is referred to as fifth surface (F5) and the other (Z2 side) as sixth surface (F6).

Conductive layer (110a) is formed on fifth surface (F5) of substrate 100, and conductive layer (110b) is formed on sixth surface (F6) of substrate 100. Holes that penetrate through substrate 100 (accommodation section (R1) and through hole 120) are formed in substrate 100. Accommodation section (R1) has a shape that corresponds to wiring board 20 (a rectangular shape, for example). Accordingly, the periphery of accommodation section (R1) substantially corresponds to the outline of wiring board 20. In addition, by forming copper-plated film, for example, on the wall surface of through hole 120, through-hole conductor 130 is formed. Conductive layer (110a) and conductive layer (110b) are electrically connected to each other by through-hole conductor 130. The shape of through hole 120 is columnar, for example.

As shown in FIG. 5, wiring board 20 (second rigid wiring board) has insulative substrate 200 (the core substrate of wiring board 20), conductive layers (210a, 210b, 211˜214), and insulation layers (201˜204). In the following, one (Z1 side) of upper and lower surfaces (two main surfaces) of substrate 200 is referred to as seventh surface (F7) and the other (Z2 side) as eighth surface (F8).

Conductive layer (210a) is formed on seventh surface (F7) of substrate 200, and conductive layer (210b) is formed on eighth surface (F8) of substrate 200. Insulation layers (201, 203) and conductive layers (211, 213) are alternately laminated on seventh surface (F7) of substrate 200, and insulation layers (202, 204) and conductive layers (212, 214) are alternately laminated on eighth surface (F8) of substrate 200.

Through hole 220 which penetrates through substrate 200 is formed in substrate 200, and becomes through-hole conductor 230 by forming copper-plated film, for example, on the wall surface of through hole 220. Then, insulator 240 made of the resin from insulation layers (201, 202), for example, is filled inside through-hole conductor 230 in through hole 220. Via holes (221, 223) are respectively formed in insulation layers (201, 203), and via conductors (231, 233) (each a filled via) are formed by filling via holes (221, 223) with copper plating, for example. Also, via holes (222, 224) are respectively formed in insulation layers (202, 204), and via conductors (232, 234) (each a filled via) are formed by filling via holes (222, 224) with copper plating, for example.

As shown in FIG. 1, wiring board 20 is accommodated in accommodation section (R1) of wiring board 10, insulation layer 301 is formed on first surface (F1) of wiring board 10 and on third surface (F3) of wiring board 20, and insulation layer 302 is formed on second surface (F2) of wiring board 10 and on fourth surface (F4) of wiring board 20. Conductive layer 311 is formed on insulation layer 301, and conductive layer 312 is formed on insulation layer 302. In the present embodiment, wiring boards (10, 20) form the core substrate of wiring board 1000, accommodation section (R1) penetrates through wiring board 10, and insulation layers (301, 302) and conductive layers (311, 312) are laminated on both surfaces of wiring boards (10, 20).

Via holes (321a, 321b) are formed in insulation layer 301, and via conductors (331a, 331b) (each a filled via) are formed by filling via holes (321a, 321b) with copper plating, for example. Also, via holes (322a, 322b) are formed in insulation layer 302, and via conductors (332a, 332b) (each a filled via) are formed by filling via holes (322a, 322b) with copper plating, for example. Via conductors (331a, 332a) are formed in their respective regions directly on wiring board 10, and via conductors (331b, 332b) are formed in their respective regions directly on wiring board 20.

Wiring board 1000 of the present embodiment has stacked-conductor structures (S1, S2) on and under the core substrate (substrate 200) of wiring board 20, for example.

Wiring board 1000 has solder resist 401 on the outermost layer (insulation layer 301 and conductive layer 311) on one side, and solder resist 402 on the outermost layer (insulation layer 302 and conductive layer 312) on the other side. Opening portions (411a, 411b) are formed in solder resist 401 and portions of the outermost conductive layer (conductive layer 311) are exposed through opening portions (411a, 411b) and become pads. Then, external connection terminals (421a, 421b) made of solder, for example, are formed respectively on the pads exposed through opening portions (411a, 411b). Also, opening portions (412a, 412b) are formed in solder resist 402 and portions of the outermost conductive layer (conductive layer 312) are exposed through opening portions (412a, 412b) and become pads. Then, external connection terminals (422a, 422b) made of solder, for example, are formed respectively on the pads exposed through opening portions (412a, 412b). External connection terminals (421a, 422a) are formed in their respective regions directly on wiring board 10, and external connection terminals (421b, 422b) are formed in their respective regions directly on wiring board 20.

Since wiring boards (10, 20) in wiring board 1000 of the present embodiment are both rigid wiring boards, it is easier to secure wiring board 20 by friction when wiring board 20 is accommodated in accommodation section (R1).

In the present embodiment, wiring board 20 (second rigid wiring board) has smaller external dimensions than wiring board 10 (first rigid wiring board) and is accommodated in accommodation section (R1) of wiring board 10. The number of conductive layers (two layers) in wiring board 10 (first rigid wiring board) is less than the number of conductive layers (six layers) in wiring board 20 (second rigid wiring board). Namely, the number of conductive layers included per unit thickness is greater in wiring board 20 than in wiring board 10. As a result, the density of existing conductors in wiring board 20 is higher than the density of existing conductors in wiring board 10. According to such a structure, the conductor density of wiring board 1000 is increased partially (to make high-density wiring). The number of layers in the first and second rigid wiring boards is not limited specifically. The first rigid wiring board may have buildup layers, and the second rigid wiring board may have eight or more conductive layers, for example.

In the present embodiment, wiring board 10 (first rigid wiring board) and wiring board 20 (second rigid wiring board) are electrically connected to each other by via conductors (331a, 331b) and conductive layer 311, or by via conductors (332a, 332b) and conductive layer 312.

Wiring board 1000 of the present embodiment has external connection terminals (421a, 422a) and (421b, 422b) respectively in regions directly on wiring board 10 (first rigid wiring board) and in regions directly on wiring board 20 (second rigid wiring board). External connection terminals (421a, 422a, 421b, 422b) are used for electrical connection with another wiring board, an electronic component or the like, for example. Wiring board 1000 may be used as a circuit board for mobile equipment (such as a cell phone) or the like by being mounted on another wiring board on one of its surfaces or both of its surfaces, for example.

Substrates (100, 200) are each made by impregnating, for example, glass cloth (core material) with epoxy resin (hereinafter referred to as glass epoxy). The core material has a lower thermal expansion coefficient than primary material (epoxy resin in the present embodiment). Inorganic material such as glass fiber (glass cloth or glass non-woven fabric, for example), aramid fiber (aramid non-woven fabric, for example), or silica filler is considered preferable as core material. However, the material of substrates (100, 200) is basically determined freely. For example, polyester resin, bismaleimide triazine resin (BT resin), imide resin (polyimide), phenol resin, allyl polyphenylene ether resin (A-PPE resin) or the like may also be used instead of epoxy resin. Each substrate may be formed with multiple layers made of different materials.

Each insulation layer in wiring board 1000 is made of glass epoxy, for example. However, that is not the only option, and the material of insulation layers is basically determined freely. For example, polyester resin, bismaleimide triazine resin (BT resin), imide resin (polyimide), phenol resin, allyl polyphenylene ether resin (A-PPE resin) or the like may also be used instead of epoxy resin. Each insulation layer may be formed with multiple layers made of different materials.

Through-hole conductors and via conductors in wiring board 1000 are each made of copper plating, for example. The shape of through-hole conductors is a column or a cylinder, for example. The shape of via conductors is a tapered column (truncated cone), for example. Via conductors formed in a buildup section taper with a diameter that increases from the core substrate toward the upper layer, for example. However, those are not the only options, and the shape of via conductors may be determined freely.

Each conductive layer in wiring board 1000 is formed with copper foil (lower layer) and copper plating (upper layer). Such a conductive layer includes, for example, wiring (inner-layer wiring) that forms electronic circuits, a land, a planar conductive pattern to enhance the strength or flatness of the wiring board, or the like. A tear-drop treatment is preferred to be conducted at the connected portion of a land and wiring.

The material of each conductive layer and each via conductor is not limited specifically as long as it is conductive. It may be metallic or non-metallic. Each conductive layer and each via conductor may be formed with multiple layers made of different materials.

Solder resists in wiring board 1000 are each made of resin such as photosensitive resin using acrylic epoxy resin, thermosetting resin mainly containing epoxy resin, or UV curable resin.

In the present embodiment, wall surface (F11) of accommodation section (R1) (side surface of wiring board 10) and side surface (F12) of wiring board 20 intersect with main surfaces of wiring board 1000 (X-Y plane, for example) at substantially a right angle. However, that is not the only option, and wall surface (F11) of accommodation section (R1) (side surface of wiring board 10) and side surface (F12) of wiring board 20 may taper (see later-described FIG. 36, for example).

In the present embodiment, insulator 140 made of resin, for example, is filled in a gap between wiring board 10 and wiring board 20 as shown in FIG. 3 and the others. Insulator 140 is filled in a gap between wiring board 10 and wiring board 20 when resin flows out from insulation layer 301 or 302, for example. However, that is not the only option, and any material may be used to form insulator 140 separately.

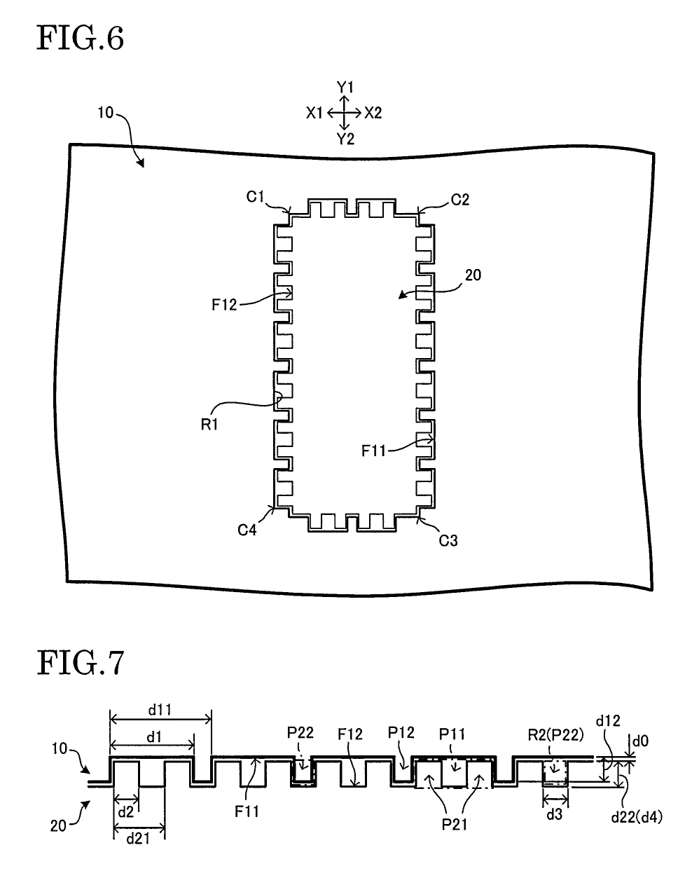

FIG. 6 shows a state in which wiring board 20 (second rigid wiring board) is accommodated in accommodation section (R1) of wiring board 10 (first rigid wiring board). Also, FIG. 7 shows the side-surface shape of wiring board 20 and the wall-surface shape of accommodation section (R1) formed in wiring board 10.

As shown in FIG. 6, a concavo-convex shape is formed respectively on side surface (F12) of wiring board 20 and on wall surface (F11) of accommodation section (R1) (side surface of wiring board 10) in the present embodiment, and each surface is formed in a zigzag pattern. The concavo-convex shape is formed by cutting. As shown in FIG. 7, concave portion (P11) and convex portion (P12) are formed on wall surface (F11) of accommodation section (R1), and convex portion (P21) and concave portion (P22) are formed on side surface (F12) of wiring board 20. A zigzag pattern means a concave portion and convex portion are alternately positioned in series.

A concavo-convex shape is formed respectively on wall surface (F11) of accommodation section (R1) (side surface of wiring board 10) and on side surface (F12) of wiring board 20 (second rigid wiring board). By doing so, resistance of wiring board 1000 is enhanced against external force caused by being dropped or the like. That is because when side surface (F12) of wiring board 20 and wall surface (F11) of accommodation section (R1) are formed in a zigzag pattern, contact areas increase between wiring board 10 and wiring board 20, and thus cracking is thought to be suppressed.

Also, a concavo-convex shape is formed entirely along each periphery of side surface (F12) of wiring board 20 and wall surface (F11) of accommodation section (R1) (side surface of wiring board 10) in the present embodiment. Accordingly, it is thought that the effects of suppressing cracks are greater than when a concavo-convex shape is formed only partially.

Wall surface (F11) of accommodation section (R1) facing side surface (F12) of wiring board 20 has a convex-concave shape that corresponds to the concavo-convex shape of side surface (F12) of wiring board 20. A convex portion faces a concave portion, and a concave portion faces a convex portion. In the present embodiment two convex portions (P21) formed on side surface (F12) of wiring board 20 are inserted in one concave portion (P11) formed on wall surface (F11) of accommodation section (R1). Then, space (R2) resulting from concave portion (P22) is formed between two convex portions (P21) inserted in one concave portion (P11). According to such a structure, the number of concavo-convex portions is reduced while suppressing a decrease in strength as much as possible. Thus, it is easier to achieve required strength (especially, the bonding strength between wiring board 10 and wiring board 20) by using fewer concavo-convex portions. Also, since the number of finer concavo-convex portions decreases, voids tend not to occur when insulator 140 is filled in a gap between wiring board 10 and wiring board 20.

The concavo-convex line of the present embodiment is such a line that rectangles are formed in series (square wave). The concavo-convex shape is preferred to have substantially a constant cycle along the entire periphery. In addition, it is preferred that concave portion (P11), convex portion (P12), convex portion (P21) and concave portion (P22) each have substantially constant dimensions along the entire periphery. If their dimensions are substantially constant, forming concavo-convex shapes is easier and concentration of stress in parts tends not to occur.

Following are preferred examples: regarding the concavo-convex shape of wall surface (F11) of accommodation section (R1), cycle (d11) is set at 2 mm and amplitude (d12) at 0.5 mm; regarding the concavo-convex shape of side surface (F12) of wiring board 20, cycle (d21) is set at 0.7 mm and amplitude (d22) at 0.5 mm; width (d3) of space (R2) (the measurement in a direction parallel to side surface (F12) of wiring board 20) is set at 0.2 mm; length (d4) of space (R2) (the measurement in a direction perpendicular to side surface (F12) of wiring board 20) is set at 0.46 mm; and distance (d0) between wall surface (F11) of accommodation section (R1) and side surface (F12) of wiring board 20 is set at 0.04 mm.

It is preferred that the cycle of the concavo-convex shape of wall surface (F11) of accommodation section (R1) or side surface (F12) of wiring board 20 be in the range of approximately 1 mm to approximately 3 mm, and the amplitude of the concavo-convex shape be in the range of approximately 0.2 mm to approximately 1 mm. If a concavo-convex shape is set too fine, it may break easily or have difficulty forming such a shape. In addition, if a concavo-convex shape is too large, such a shape may compress regions for forming wiring.

In the present embodiment, length (d4) of space (R2) formed between convex portions (P21) inserted in concave portion (P11) is substantially the same as the length (amplitude (d22)) of convex portion (P21) as shown in FIG. 7. According to such a structure, uniform dimensions make it easier to form a concavo-convex shape on side surface (F12) of wiring board 20 and to suppress concentration of stress in parts.

Width (d1) of concave portion (P11) is preferred to be in the range of 0.5 to 0.8 times the cycle (d11). Length (d2) of convex portion (P21) is preferred to be in the range of 0.5 to 0.8 times the cycle (d21).

Width (d3) of space (R2) is preferred to be in the range of 0.2 to 0.5 times the width (d2) of convex portion (P21). Width (d4) of space (R2) is preferred to be in the range of 0.85 to 0.95 times the amplitude (d22).

Wiring board 1000 of the present embodiment has through-hole conductor 530 (joint conductor). As shown in FIG. 3, multiple through-hole conductors 530 are positioned, for example, along boundary line (L1) between wiring board 10 and wiring board 20. More specifically, through-hole conductors 530 are positioned in all corners (C1˜C4) of wiring board 20, and through-hole conductors 530 are also positioned on sides of wiring board 20 (for example, between corner (C1) and corner (C4) and between corner (C2) and corner (C3)) in the present embodiment. As shown in FIGS. 1 and 3, each through-hole conductor 530 is formed in through hole 520 which penetrates through both wiring boards (10, 20), and connects wall surface (F11) of accommodation section (R1) (side surface of wiring board 10) and side surface (F12) of wiring board 20. Accordingly, since connected portions of wiring board 10 and wiring board 20 are reinforced by being joined by through-hole conductors 530, cracking seldom occurs when external force is exerted because of impact from being dropped or the like. Also, when cracking occurs, such cracking is thought to be suppressed from spreading because cracking tends to be blocked by through-hole conductors 530. Positions of through-hole conductors 530 are not limited to those shown in FIG. 3, and may be determined freely.

In addition, heat dissipation in wiring board 1000 improves by through-hole conductor 530.

Through-hole conductor 530 (joint conductor) may be used only for heat dissipation. However, through-hole conductor 530 is also used electrically in the present embodiment. Namely, conductive layer 311 and conductive layer 312 are electrically connected to each other by through-hole conductor 530. Since through-hole conductor 530 is a filled conductor and is easier to set wide, it is preferred to be connected to power source or ground. However, through-hole conductor 530 (joint conductor) is not limited to being a filled conductor, and may be a conformal conductor, for example.

Through hole 520 penetrates through insulation layers (301, 302) as well as wiring board 10 and wiring board 20. Both ends of through-hole conductor 530 are connected respectively to the outermost conductive layers (conductive layers (311, 312)) of wiring board 1000. Through-hole conductor 530 is made by filling through hole 520 with copper plating, for example. By using the same material for through-hole conductor 530 as that for via conductors (331a, 331b, 332a, 332b), it is easier to form them simultaneously. As a result, manufacturing efficiency improves.

In the present embodiment, planar conductive film (in particular, lands (311a, 312a)) is formed on a boundary portion (boundary line (L1)) between wiring board 10 and wiring board 20 as shown in FIG. 3A. Then, both ends of through-hole conductor 530 are respectively connected to lands (311a, 312a) as shown in FIG. 1. Accordingly, connection by through-hole conductor 530 at a connected portion of wiring board 10 and wiring board 20 is strengthened.

In the present embodiment, lands (311a, 312a) are made of planar conductive film (specifically, in a disc shape). However, that is not the only option, and through-hole conductor 530 set to be a conformal conductor may be connected to ring-shaped lands.

Also, in the present embodiment, planar conductive films (311c, 312c) are formed directly on the boundary portion (boundary line (L1)) between wiring board 10 and wiring board 20 as shown in FIG. 3. Conductive films (311c, 312c) are extended along boundary line (L1) between wiring board 10 and wiring board 20, for example. More specifically, conductive films (311c, 312c) each have a rectangular planar shape (on the X-Y plane), positioned on sides of wiring board 20 (between corner (C1) and corner (C2) and between corner (C3) and corner (C4), for example), and the directions parallel to the sides are their longitudinal directions. Conductive films (311c, 312c) are each connected to ground, for example.

Land (311a), wiring (311b) connected to that land, and conductive film (311c) are each included in conductive layer 311. Land (312a), wiring (312b) connected to that land, and conductive film (312c) are each included in conductive layer 312.

In the present embodiment, through-hole conductor 530 (joint conductor), conductors in wiring board 10 (through-hole conductors and conductive layers), conductors in wiring board 20 (through-hole conductors, via conductors, conductive layers) are all made of the same material (such as copper). In doing so, it is easier to form each conductor.

In the following, a method for manufacturing wiring board 1000 according to the present embodiment is described.

When manufacturing wiring board 1000 of the present embodiment, first, wiring board 10 and wiring board 20 are respectively manufactured.

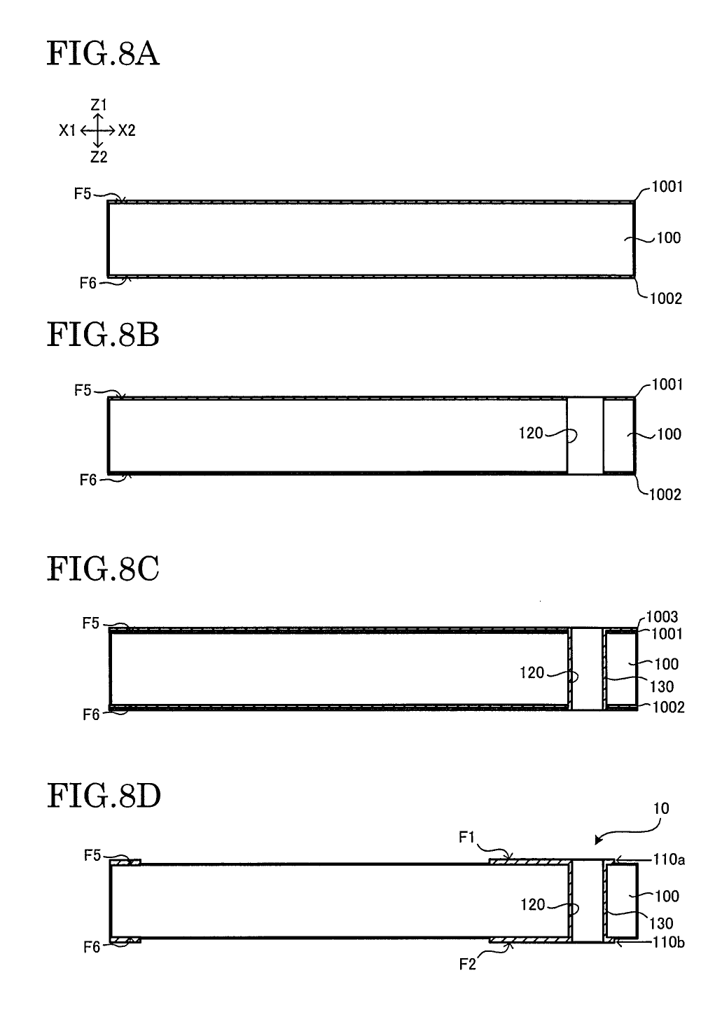

To manufacture wiring board 10, first, substrate 100 having copper foil 1001 on fifth surface (F5) and copper foil 1002 on sixth surface (F6) is prepared as shown in FIG. 8A, for example. A copper-clad laminate may be used, for example, as such starting material. As shown in FIG. 8B, a drill or a laser, for example, is used to form through hole 120. Then, desmearing is conducted if required.

Copper panel plating (such as electroless plating and electrolytic plating), for example, is performed. Accordingly, plated film 1003 is formed on copper foils (1001, 1002) and in through hole 120 as shown in FIG. 8C. Plated film 1003 formed on the wall surface of through hole 120 becomes through-hole conductor 130.

Using photo-etching techniques (acid cleansing, resist lamination, exposure and development, etching, film removal, and the like), for example, conductive layers formed on fifth surface (F5) and sixth surface (F6) of substrate 100 are each patterned. In doing so, conductive layers (110a, 110b) are formed as shown in FIG. 8D. Accordingly, wiring board 10 is completed.

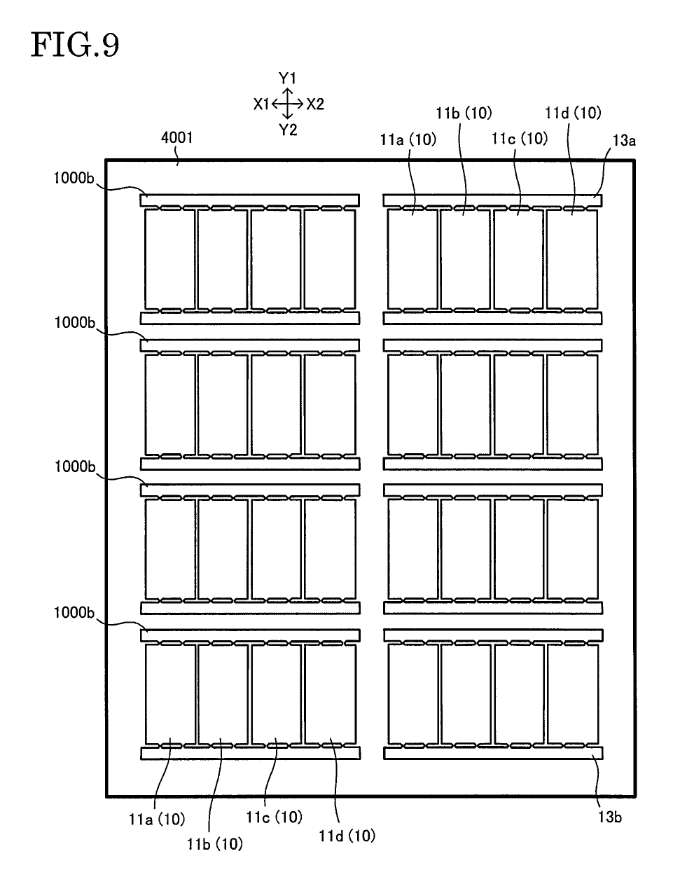

In the present embodiment, multiple frame units (1000b) (frame units (1000a) prior to accommodating wiring boards 20) are formed collectively in one panel 4001 as shown in FIG. 9. Frame units (1000b) are each formed with multiple wiring boards 10 set in an integrated fashion (see FIG. 2).

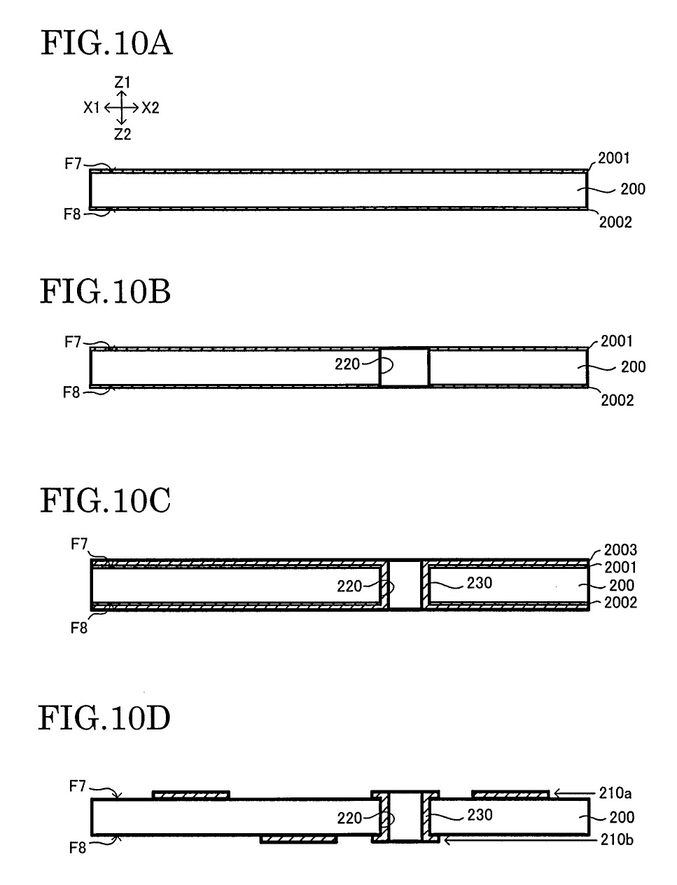

On the other hand, when wiring board 20 is manufactured, substrate 200 having copper foil 2001 on seventh surface (F7) and copper foil 2002 on eighth surface (F8) is first prepared as shown in FIG. 10A, for example. A copper-clad laminate is used for such starting material, for example. Using a drill or a laser, for example, through hole 220 is formed as shown in FIG. 10B. Then, desmearing is conducted if required.

Copper panel plating (such as electroless plating and electrolytic plating), for example, is conducted. In doing so, plating 2003 is formed on copper foils (2001, 2002) and in through hole 220 as shown in FIG. 10C. Plated film 2003 formed on the wall surface of through hole 220 becomes through-hole conductor 230.

Using photo-etching techniques (acid cleansing, resist lamination, exposure and development, etching, film removal, and the like), for example, conductive layers formed on seventh surface (F7) and eighth surface (F8) of substrate 200 are each patterned. In doing so, conductive layers (210a, 210b) are formed as shown in FIG. 10D. After that, surfaces of conductive layers (210a, 210b) are roughened if required.

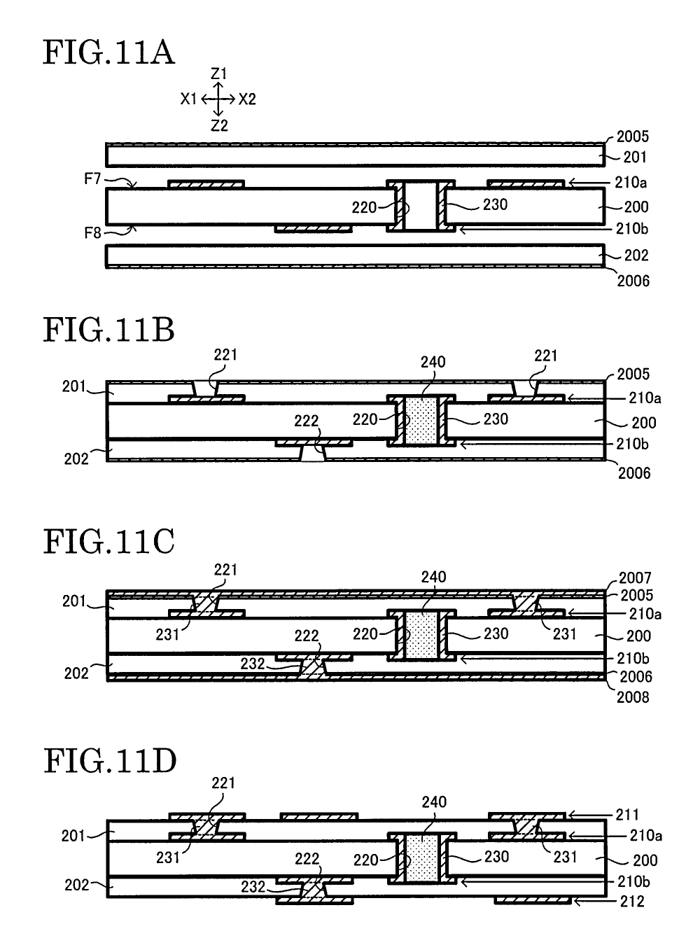

As shown in FIG. 11A, insulation layer 201 having copper foil 2005 is positioned on seventh surface (F7) of substrate 200, and insulation layer 202 having copper foil 2006 is positioned on eighth surface (F8) of substrate 200. Insulation layers (201, 202) are each made of prepreg, for example.

Using hydraulic pressing equipment, for example, outer copper foils (2005, 2006) are pressurized. Specifically, pressing and thermal treatments are conducted simultaneously. Through thermal pressing, insulation layers (201, 202) are pressed in directions Z, prepreg (insulation layers (201, 202)) is cured, and insulation layers (201, 202) and substrate 200 are adhered. As a result, the laminate becomes integrated. In addition, during pressing, resin flows out from insulation layers (201, 202) and is filled in through hole 220. The resin filled in through hole 220 becomes insulator 240 (see FIG. 11B). Pressing and thermal treatments may be divided into multiple procedures. In addition, thermal and pressing treatments may be conducted separately, but it is more efficient if they are conducted simultaneously. After thermal pressing, another thermal treatment for integration may be conducted separately.

As shown in FIG. 11B, a laser, for example, is used to form via hole 221 in insulation layer 201 and via hole 222 in insulation layer 202. Then, desmearing is conducted if required.

Copper panel plating (such as electroless plating and electrolytic plating), for example, is performed. Accordingly, platings (2007, 2008) are formed respectively on copper foils (2005, 2006) and in via holes (221, 222) as shown in FIG. 11C. Platings (2007, 2008) filled in via holes (221, 222) respectively become via conductors (231, 232).

Using photo-etching techniques (acid cleansing, resist lamination, exposure and development, etching, film removal, and the like), for example, conductive layers formed on insulation layers (201, 202) are each patterned. Accordingly, conductive layers (211, 212) are formed as shown in FIG. 11D. Then, surfaces of conductive layers (211, 212) are roughened if required.

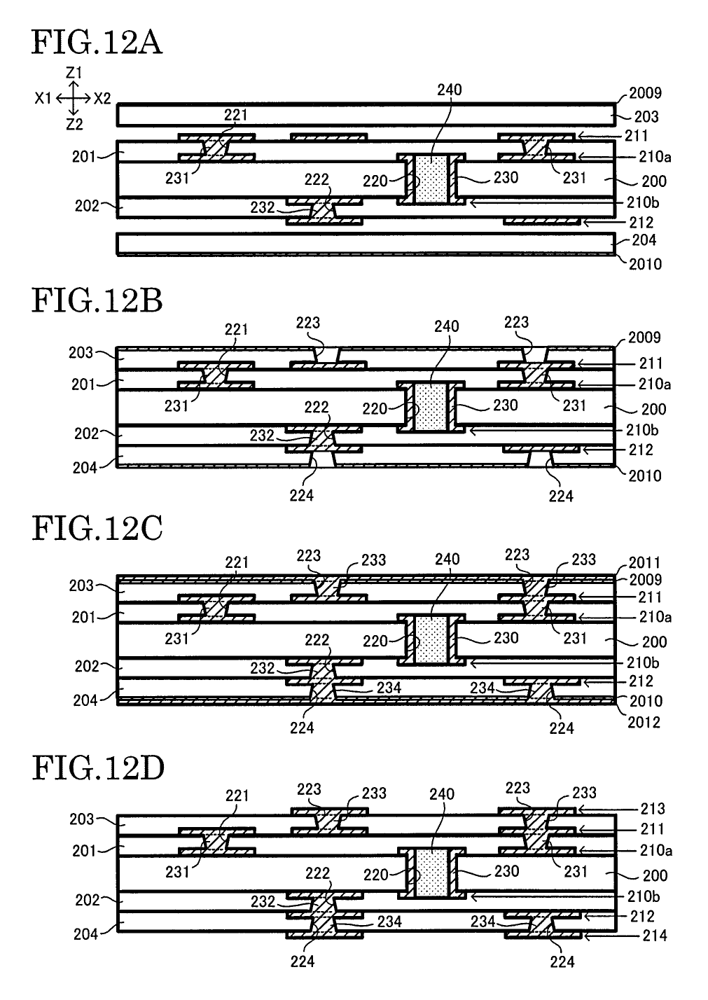

As shown in FIG. 12A, insulation layer 203 with copper foil 2009 is positioned on insulation layer 201 and conductive layer 211, and insulation layer 204 with copper foil 2010 is positioned on insulation layer 202 and conductive layer 212. Insulation layers (203, 204) are each made of prepreg, for example.

Using hydraulic pressing equipment, for example, outer copper foils (2009, 2010) are pressurized the same as in the first layers (insulation layers (201, 202)), for example. Accordingly, insulation layers (203, 204) are pressed, and insulation layers (203, 204) and substrate 200 are adhered to be integrated.

A laser, for example, is used to form via hole 223 in insulation layer 203 and via hole 224 in insulation layer 204, as shown in FIG. 12B. Then, desmearing is conducted if required.

Copper panel plating (such as electroless plating and electrolytic plating), for example, is performed. Accordingly, platings (2011, 2012) are formed respectively on copper foils (2009, 2010) and in via holes (223, 224) as shown in FIG. 12C. Platings (2011, 2012) filled in via holes (223, 224) become via conductors (233, 234) respectively.

Using photo-etching techniques (acid cleansing, resist lamination, exposure and development, etching, film removal, and the like), for example, conductive layers formed on insulation layer 203 and insulation layer 204 are each patterned. In doing so, conductive layers (213, 214) are formed as shown in FIG. 12D. Then, surfaces of conductive layers (213, 214) are roughened if required. Accordingly, wiring board 20 is completed.

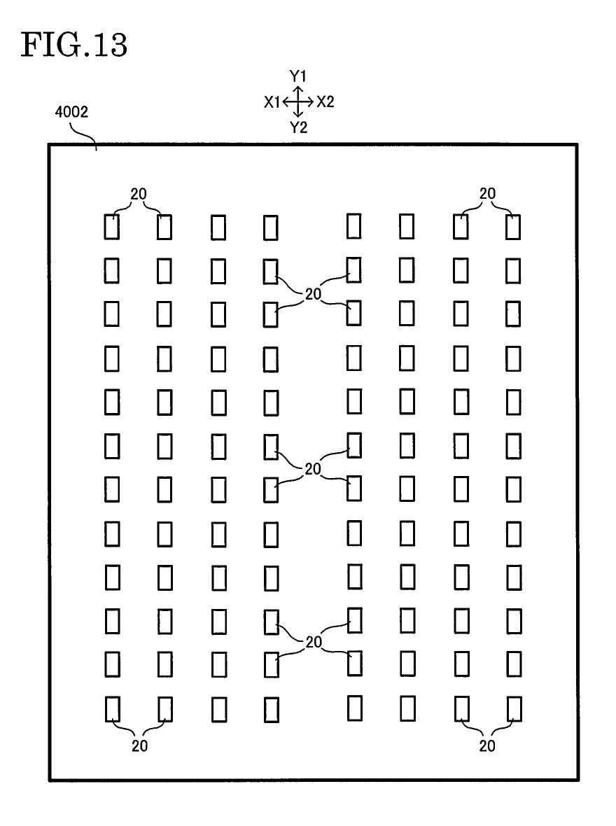

In the present embodiment, multiple wiring boards 20 are formed collectively in one panel 4002 as shown in FIG. 13.

Accommodation section (R1) is formed in each wiring board 10. During that time, wall surface (F11) of accommodation section (R1) is formed in a zigzag pattern as shown in FIGS. 6 and 7.

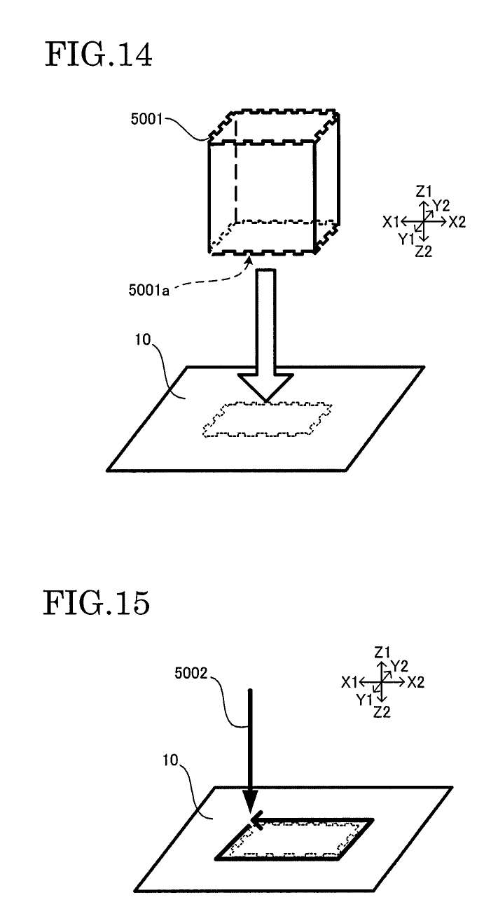

Specifically, accommodation section (R1) is formed in wiring board 10 using die 5001 shaped in a rectangular column as shown in FIG. 14, for example. The concavo-convex shape of opening surface (5001a) of die 5001 corresponds to the concavo-convex shape of wall surface (F11) of accommodation section (R1). Then, die 5001 is pressed multiple times (twice, for example) to form accommodation section (R1) in wiring board 10 as shown in FIGS. 6 and 7, based on the shape of opening surface (5001a) of die 5001. The material of die 5001 is steel, for example. The thickness of die 5001 is approximately 30 mm, for example.

Alternatively, as shown in FIG. 15, for example, laser 5002 may also be used to form accommodation section (R1). Laser 5002 is irradiated in a zigzag pattern to correspond to the shape of accommodation section (R1). By cutting out a predetermined section of wiring board 10 using laser 5002, accommodation section (R1) is formed in a zigzag pattern as shown in FIGS. 6 and 7.

However, the method for forming accommodation section (R1) is not limited to those above, and a router, for example, may be used to cut wiring board 10 so that accommodation section (R1) is formed as shown in FIGS. 6 and 7.

When forming accommodation section (R1), it is preferred that alignment marks (such as conductive patterns) readable by X rays be formed in four corners of wiring board 10, and accommodation section (R1) be formed at a predetermined position based on the alignment marks. Also, deburring may be conducted on cut surfaces if required.

Side surface (F12) of wiring board 20 is also formed in a zigzag pattern as shown in FIGS. 6 and 7. As for the method for forming a concavo-convex shape on side surface (F12) of wiring board 20, a die or a laser may be used the same as in wall surface (F11) of accommodation section (R1), for example (see FIGS. 14, 15). The die to be used for forming wiring board 20 may the same as or different from the die to be used for forming accommodation section (R1). However, to fit them highly accurately, it is preferred to prepare a special die for each of them.

In the present embodiment, the concavo-convex shape of wall surface (F11) of accommodation section (R1) is formed to correspond to the concavo-convex shape of side surface (F12) of wiring board 20. In particular, a concavo-convex shape is formed respectively on side surface (F12) of wiring board 20 and wall surface (F11) of accommodation section (R1) in such a way that multiple (two, for example) convex portions (P21) on side surface (F12) of wiring board 20 are inserted in concave portion (P11) on wall surface (F11) of accommodation section (R1) (see FIGS. 6, 7). There is no specific order when to form the concavo-convex shape on wall surface (F11) of accommodation section (R1) and the concavo-convex shape on side surface (F12) of wiring board 20, and either one may be formed first. When side surface (F12) of wiring board 20 is formed in a zigzag pattern, it is preferred that alignment marks (such as conductive patterns) readable by X rays be formed in the four corners of wiring board 20 and a zigzag pattern be formed based on such alignment marks. In addition, deburring or the like may be performed on cut surfaces if required.

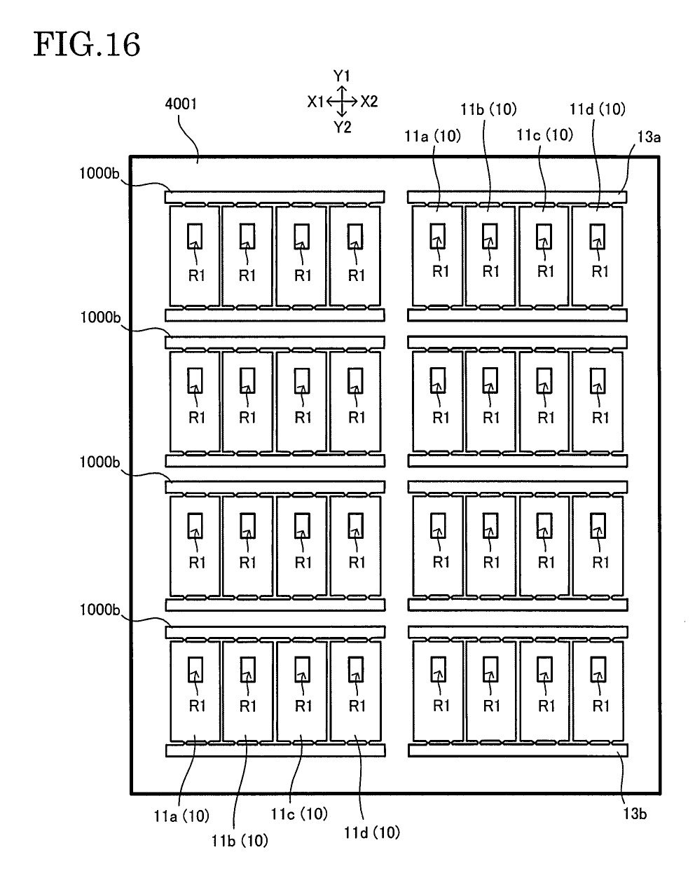

Through the above procedures, accommodation section (R1) is formed in each wiring board 10 in frame unit (1000b) as shown in FIG. 16. In addition, individual wiring board 20 is taken out from panel 4002 (FIG. 13).

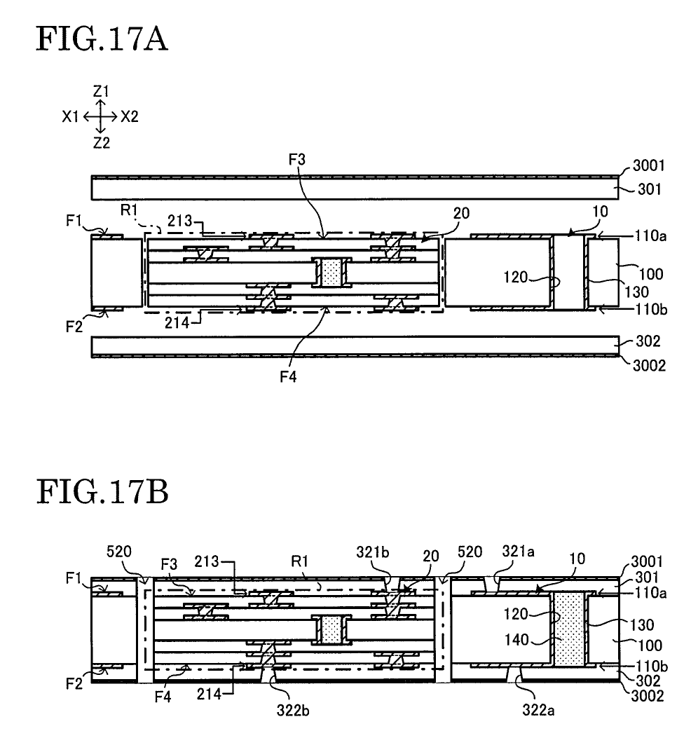

Wiring board 20 is positioned in accommodation section (R1) formed in wiring board 10 (see FIG. 17A). Then, wiring board 20 is preliminarily secured if required. During that time, if the external dimensions of wiring board 20 substantially correspond to those of accommodation section (R1), wiring board 20 is preliminarily secured by friction when fit into the accommodation section. Wiring board 20 may also be preliminarily secured using adhesives or the like.

As shown in FIG. 17A, insulation layer 301 with copper foil 3001 is positioned on first surface (F1) of wiring board 10 and on third surface (F3) of wiring board 20, and insulation layer 302 with copper foil 3002 is positioned on second surface (F2) of wiring board 10 and on fourth surface (F4) of wiring board 20. Insulation layers (301, 302) are each made of prepreg, for example.

Using hydraulic pressing equipment, for example, outer copper foils (3001, 3002) are pressurized. Specifically, pressing and thermal treatments are conducted simultaneously. Through the thermal pressing, insulation layers (301, 302) are pressed in directions Z, prepreg (insulation layers (301, 302)) is cured, and insulation layers (301, 302) and wiring boards (10, 20) are adhered. As a result, the laminate becomes integrated. Also, resin of each insulation layer flows out from insulation layers (301, 302) by pressing and is filled in through hole 120. The resin filled in through hole 120 becomes insulator 140 (see FIG. 17B). Pressing and thermal treatments may be conducted by being divided into multiple treatments. Also, thermal and pressing treatments may be conducted separately, but it is more efficient if they are conducted simultaneously. After thermal pressing, another thermal treatment for integration may be conducted separately.

As shown in FIG. 17B, a laser is used, for example, to form via holes (321a, 321b) in insulation layer 301 and via holes (322a, 322b) in insulation layer 302. Through hole 520 which penetrates through the entire laminate (wiring boards (10, 20), insulation layers (301, 302) and copper foils (3001, 3002)) is further formed. Via holes (321a, 321b, 322a, 322b) and through hole 520 may be formed simultaneously or separately. Those via holes and through hole may be formed by any method. For example, through hole 520 may be formed using a drill. After through hole 520 is formed, desmearing is conducted if required.

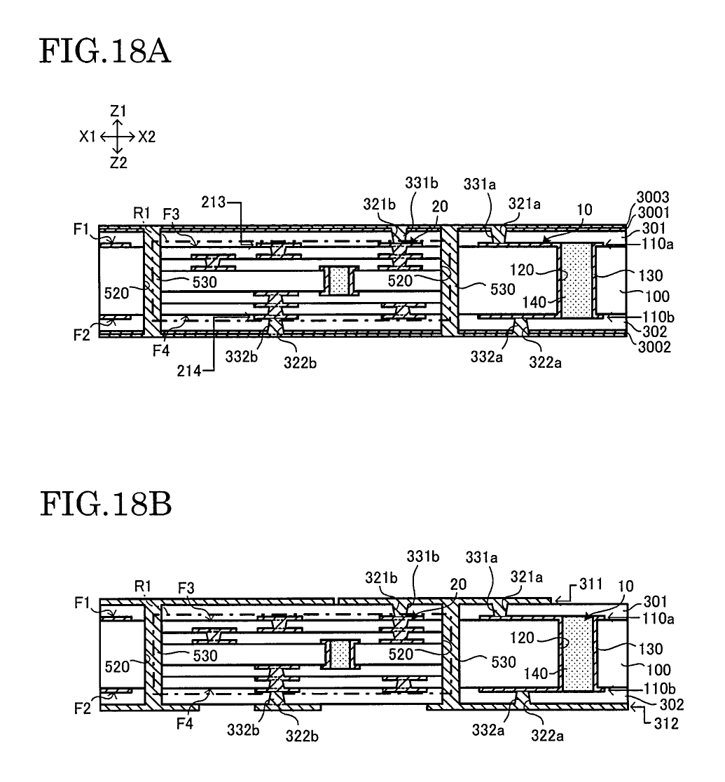

Copper panel plating (such as electroless plating and electrolytic plating), for example, is performed. Accordingly, plating 3003 is formed on copper foils (3001, 3002), in via holes (321a, 321b) and in through hole 520 as shown in FIG. 18A. Plating 3003 filled in via holes (321a, 321b) respectively becomes via conductors (331a, 331b), and plating 3003 filled in via holes (322a, 322b) respectively becomes via conductors (332a, 332b). Also, plating 3003 filled in through hole 520 becomes through-hole conductor 530 (joint conductor).

Using photo-etching techniques (acid cleansing, resist lamination, exposure and development, etching, film removal, and the like), for example, conductive layers formed on insulation layers (301, 302) are each patterned. In doing so, conductive layers (311, 312) are formed as shown in FIG. 18B. Conductive layer 311 and conductive layer 312 are electrically connected to each other by through-hole conductor 530. Specifically, lands (311a, 312a) (FIG. 3) are connected to both ends of through-hole conductor 530. Then, surfaces of conductive layers (311, 312) are roughened if required.

By screen printing, spray coating, roll coating or the like, for example, solder resist 401 having opening portions (411a, 411b) is formed on insulation layer 301 and on conductive layer 311, and solder resist 402 having opening portions (412a, 412b) is formed on insulation layer 302 and on conductive layer 312 (see FIG. 1). Accordingly, portions of conductive layer 311 are exposed through opening portions (411a, 411b) and portions of conductive layer 312 are exposed through opening portions (412a, 412b) (see FIG. 1).

External connection terminals (421a, 421b, 422a, 422b) are formed respectively in opening portions (411a, 411b, 412a, 412b) (see FIG. 1). Those external connection terminals are formed, for example, by applying solder paste and by curing the paste through thermal treatments such as reflow.

Through the above procedures, wiring board 1000 (FIG. 1) is completed, which includes wiring board 10 (first rigid wiring board) having accommodation section (R1), wiring board 20 (second rigid wiring board) accommodated in accommodation section (R1), and insulation layers (301, 302) formed on wiring boards (10, 20). A concavo-convex shape is formed on side surface (F12) of wiring board 20 and on wall surface (F11) of accommodation section (R1). Multiple convex portions (P21) formed on side surface (F12) of wiring board 20 are inserted in concave portion (P11) formed on wall surface (F11) of accommodation section (R1) (see FIGS. 6, 7).

In the manufacturing method according to the present embodiment, wiring board 20, having high-density wiring whose manufacturing procedures are complex, is manufactured separately from wiring board 10. Therefore, wiring board 20 is inspected before being accommodated in accommodation section (R1) of wiring board 10 so that only non-defective wiring board 20 is accommodated in accommodation section (R1) of wiring board 10. As a result, the production yield of wiring boards 1000 improves.

The present invention is not limited to the embodiment above. For example, the present invention may be modified as follows.

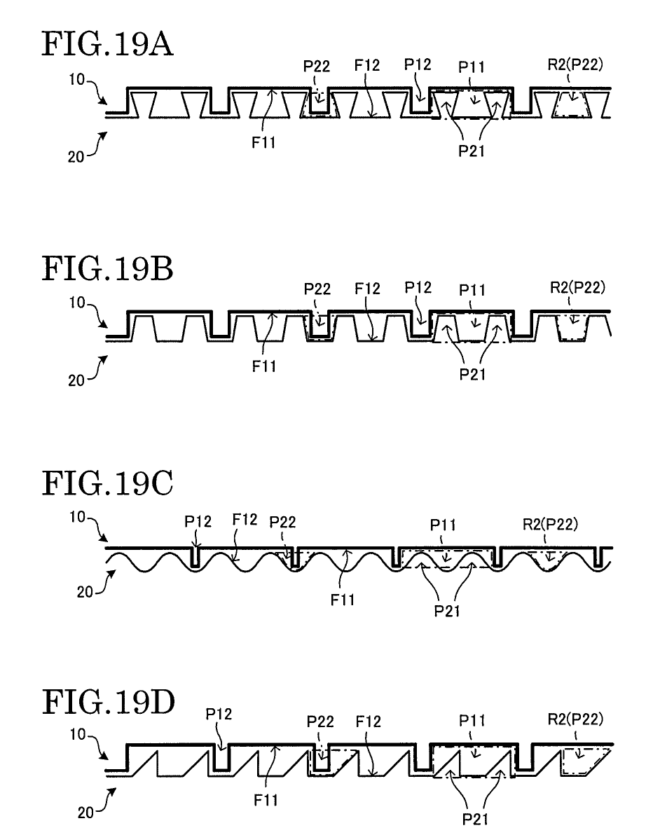

As shown in FIG. 19A or 19B, the concavo-convex line may be a trapezoid wave.

As shown in FIG. 19A, convex portion (P21) may be a trapezoid with its width increasing toward its tip. In such a case, concave portion (P22) (including space (R2)) is a trapezoid that faces the opposite direction of convex portion (P21).

As shown in FIG. 19B, convex portion (P21) may be a trapezoid with its width decreasing toward its tip. In such a case, concave portion (P22) (including space (R2)) is a trapezoid that faces the opposite direction of convex portion (P21).

As shown in FIG. 19C, the concavo-convex line may be an arc line (such as a sine wave).

As shown in FIG. 19D, it may also be a line where triangles are formed in series (such as a sawtooth wave).

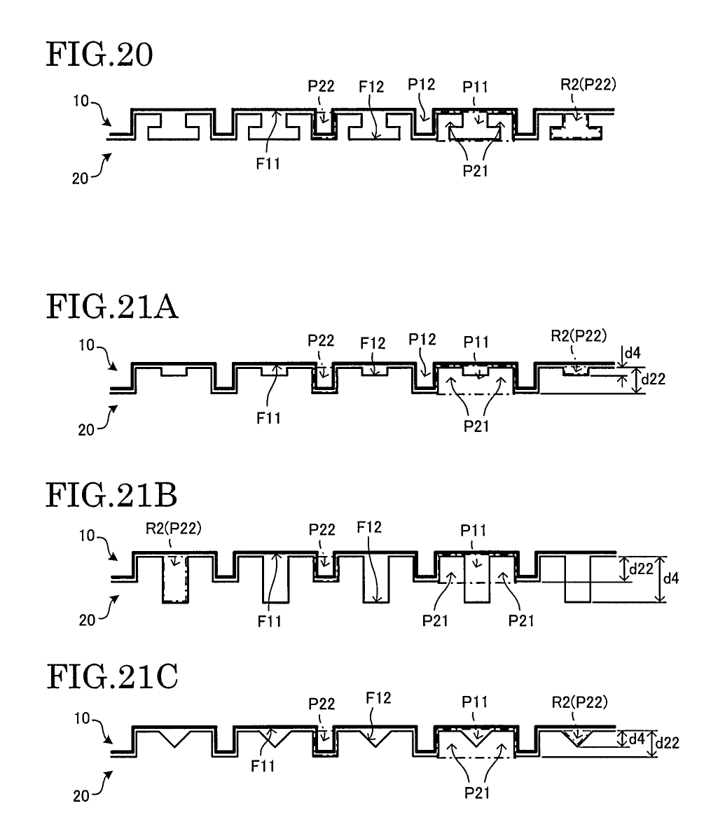

The concavo-convex shape is not always required to be a constant shape. For example, as shown in FIG. 20, when convex portion (P21) is formed in an L shape on a plane, the direction of every other convex portion (P21) may be alternated so that adjacent convex portions (P21) in concave portion (P11) are positioned symmetrically. Also, the shape of concave portion (P22) in concave portion (P11) (space R2) may be different from the shape of concave portion (P22) between concave portions (P11).

As shown in FIGS. 21A˜21C, length (d4) of space (R2) formed between convex portions (P21) inserted in concave portion (P11) may be different from the length (amplitude (d22)) of convex portion (P21). In the example in FIG. 21A, length (d4) of space (R2) is shorter than the length of convex portion (P21) (amplitude (d22)). In the example in FIG. 21B, length (d4) of space (R2) is greater than the length of convex portion (P21) (amplitude (d22)). When setting length (d4) of space (R2) to be shorter, space (R2) is preferred to taper with the width decreasing as it goes deeper, as shown in FIG. 21C, for example. By setting space (R2) to taper in a longitudinal direction, it is easier to reduce length (d4) of space (R2). In the example in FIG. 21C, space (R2) is formed in a triangular shape, and convex portions (P21) divided by space (R2) each have a width decreasing toward their respective tips.

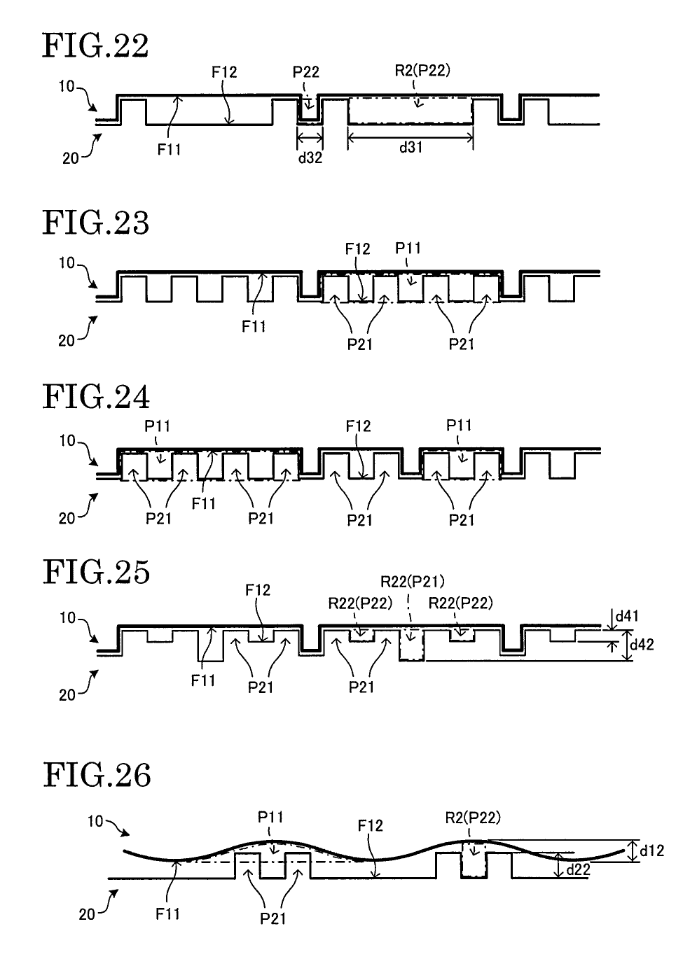

As shown in FIG. 22, width (d31) of concave portion (P22) in concave portion (P11) (space (R2)) may be different from width (d32) of concave portion (P22) between concave portions (P11). In the example in FIG. 22, width (d31) is set greater than width (d32).

The number of convex portions (P21) to be inserted in one concave portion (P11) is not limited to two. For example, three or more (four, for example) convex portions (P21) may be inserted in one concave portion (P11) as shown in FIG. 23. Alternatively, as shown in FIG. 24, for example, the number of convex portions (P21) to be inserted may be different in each concave portion (P11).

As shown in FIG. 25, lengths (d41, d42) of multiple concave portions (P22) positioned in concave portion (P11) (spaces (R21, R22)) may be different from each other. In the example in FIG. 25, length (d41) of space (R21) is set shorter than length (d42) of space (R22).

As shown in FIG. 26, the shape of wall surface (F11) of accommodation section (R1) (side surface of wiring board 10) may be different from the shape of side surface (F12) of wiring board 20. In the example in FIG. 26, the concavo-convex line on wall surface (F11) of accommodation section (R1) is a sine wave, while the concavo-convex line on side surface (F12) of wiring board 20 is a square wave. Also, amplitude (d12) of the concavo-convex shape of wall surface (F11) of accommodation section (R1) may be different from amplitude (d22) of the concavo-convex shape of side surface (F12) of wiring board 20.

The cycle or the size of a concavo-convex shape may be variable or constant. In addition, a concavo-convex shape may be determined freely. The numbers of concave portions and convex portions are not limited specifically, and the cycle of a concavo-convex shape may be a constant cycle or a variable cycle.

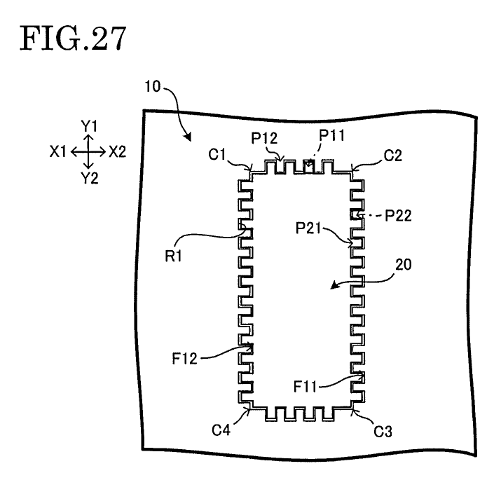

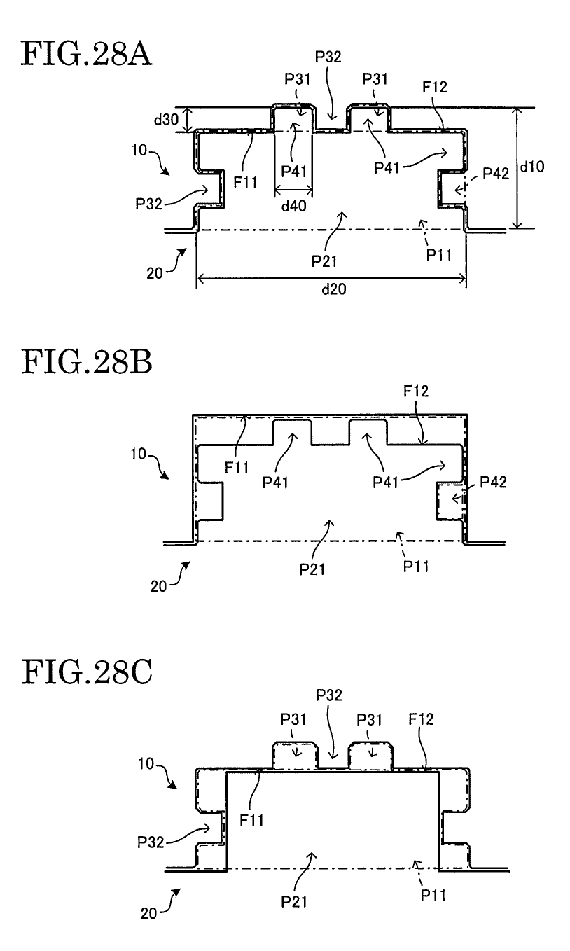

As shown in FIG. 27, a first concavo-convex shape (concave portion (P11), convex portion (P12), convex portion (P21), concave portion (P22)) may be formed on side surface (F12) of wiring board 20 (second rigid wiring board) and on wall surface (F11) of accommodation section (R1) (side surface of wiring board 10), and one convex portion (P21) formed on side surface (F12) of wiring board 20 may be inserted into one concave portion (P11) formed on wall surface (F11) of accommodation section (R1). Alternatively, as shown in FIGS. 28A˜28C, a second concavo-convex shape (concave portion (P31), convex portion (P32), convex portion (P41), concave portion (P42)), which is set finer than a first concavo-convex shape (concave portion (P11), convex portion (P12), convex portion (P21), concave portion (P22)), may be formed in at least either concave portion (P11) or convex portion (P21). In examples shown in FIGS. 28A˜28C, the length (amplitude) and width of the second concavo-convex shape are set shorter than the length (amplitude) and width of the first concavo-convex shape. Corners of the second concavo-convex shape are preferred to be roundish. The first concavo-convex shape and the second concavo-convex shape may be formed by the same method or by different methods. The second concavo-convex shape is preferred to be formed by using a laser, router or die, for example.

In the example in FIG. 28A, a second concavo-convex shape (concave portion (P31), convex portion (P32), convex portion (P41), concave portion (P42)) is formed in each concave portion (P11) and in each convex portion (P21).

In the example in FIG. 28B, regarding concave portion (P11) and convex portion (P21), a second concavo-convex shape (convex portion (P41) and concave portion (P42)) is formed only in convex portion (P21).

In the example in FIG. 28C, regarding concave portion (P11) and convex portion (P21), a second concavo-convex shape (concave portion (P31) and convex portion (P32)) is formed only in concave portion (P11).

In FIG. 28A, amplitude (d10) of the first concavo-convex shape (concave portion (P11), convex portion (P12), convex portion (P21), concave portion (P22)) is preferred to be in the range of approximately 3 times to approximately 15 times the amplitude (d30) of the second concavo-convex shape (concave portion (P31), convex portion (P32), convex portion (P41), concave portion (P42)).

In FIG. 28A, width (d20) of the first concavo-convex shape (concave portion (P11), convex portion (P12), convex portion (P21), concave portion (P22)) is preferred to be in the range of approximately 3 times to approximately 15 times the width (d40) of the second concavo-convex shape (concave portion (P31), convex portion (P32), convex portion (P41), concave portion (P42)).

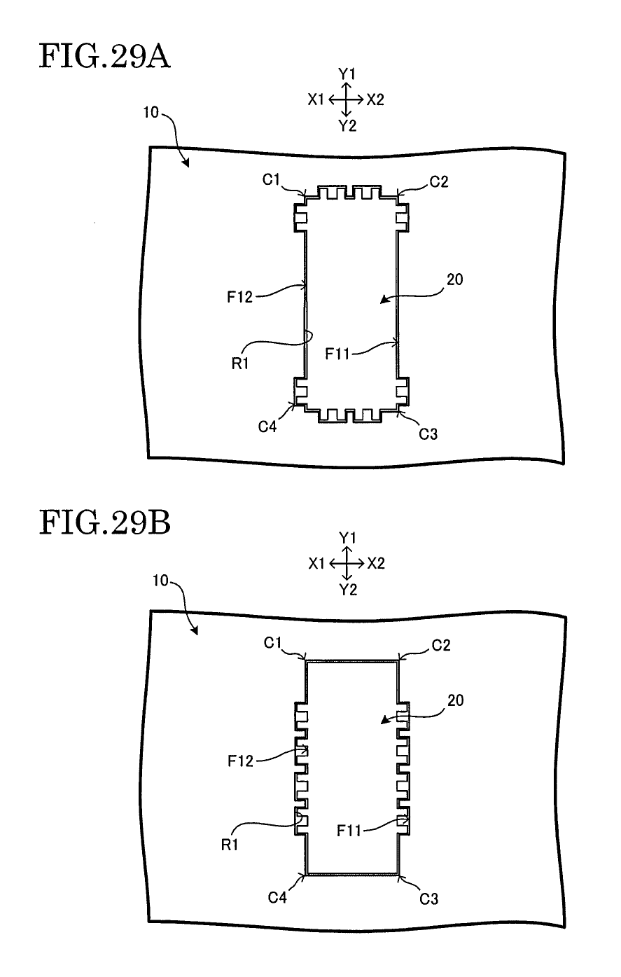

To suppress cracking or the like, side surface (F12) of wiring board 20 and wall surface (F11) of accommodation section (R1) (side surface of wiring board 10) are each preferred to have a concavo-convex shape for the entire periphery. However, that is not the only option. For example, even if surfaces are formed partially in a straight line as shown in FIGS. 29A and 29B, certain effects are achieved.

As shown in FIG. 29A, side surface (F12) of wiring board 20 and wall surface (F11) of accommodation section (R1) may each have a concavo-convex shape only near a corner.

As shown in FIG. 29B, side surface (F12) of wiring board 20 and wall surface (F11) of accommodation section (R1) may each have a concavo-convex shape only in a region along a side.

It is preferred that regions making up 50% or greater of the entire periphery of wiring board 20 be formed in a zigzag pattern.

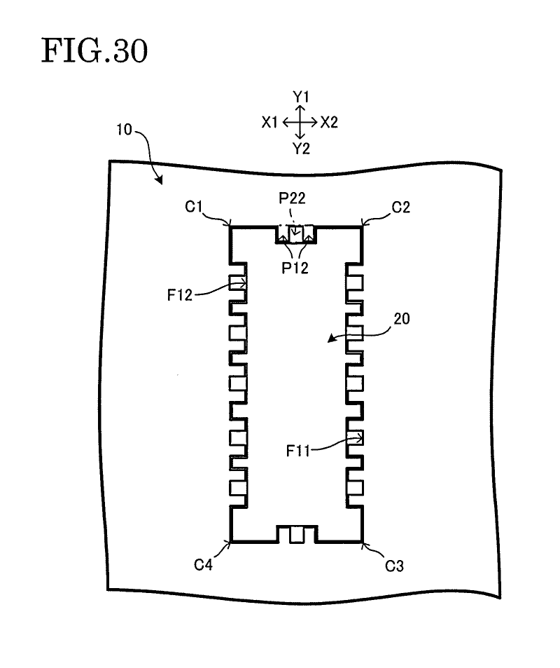

In the embodiment above, multiple convex portions (P21) formed on side surface (F12) of wiring board 20 are inserted into concave portion (P11) formed on wall surface (F11) of accommodation section (R1). However, that is not the only option. For example, multiple convex portions (P12) formed on wall surface (F11) of accommodation section (R1) may be inserted into concave portion (P22) formed on side surface (F12) of wiring board 20, as shown in FIG. 30.

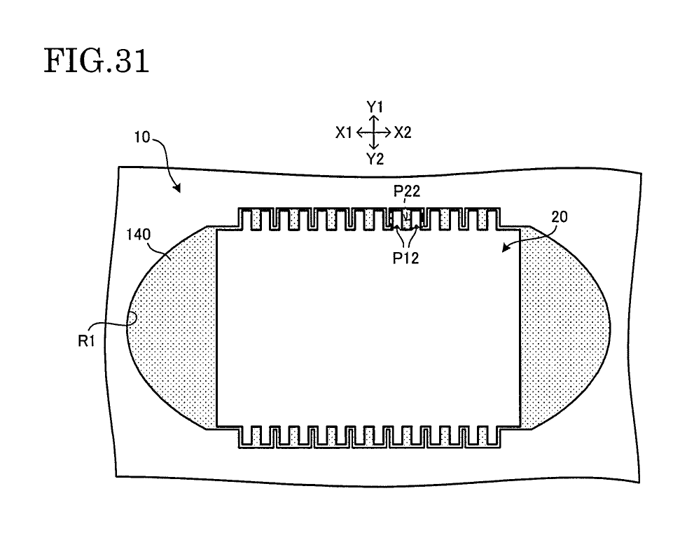

The planar shapes (X-Y plane) of wiring board 10 (first rigid wiring board), wiring board 20 (second rigid wiring board) and accommodation section (R1) are not limited specifically. The planar shape of wiring board 20 is not always required to correspond to the planar shape of accommodation section (R1). For example, as shown in FIG. 31, it is an option for the planar shape of wiring board 20 not to be similar to the planar shape of accommodation section (R1). In the example in FIG. 31, the planar shape of wiring board 20 is a rectangle, and the planar shape of accommodation section (R1) is an ellipse.

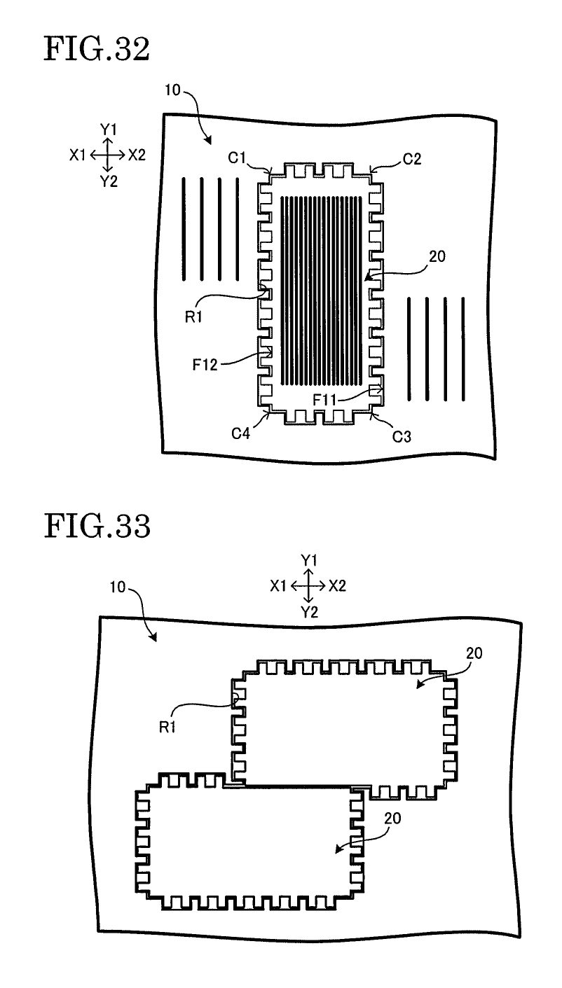

As shown in FIG. 32, the density of conductive patterns in wiring board 20 (second rigid wiring board) may be higher than the density of conductive patterns in wiring board 10 (first rigid wiring board). In such a case as well, since the density of existing conductors in wiring board 20 is higher than the density of existing conductors in wiring board 10, the conductor density of wiring board 1000 may be partially set higher (set as high-density wiring). The density of conductive patterns increases as L (line)/S (space) becomes narrower.

As shown in FIG. 33, multiple (such as two) wiring boards 20 (second rigid wiring boards) may be accommodated in one accommodation section (R1) formed in wiring board 10 (first rigid wiring board).

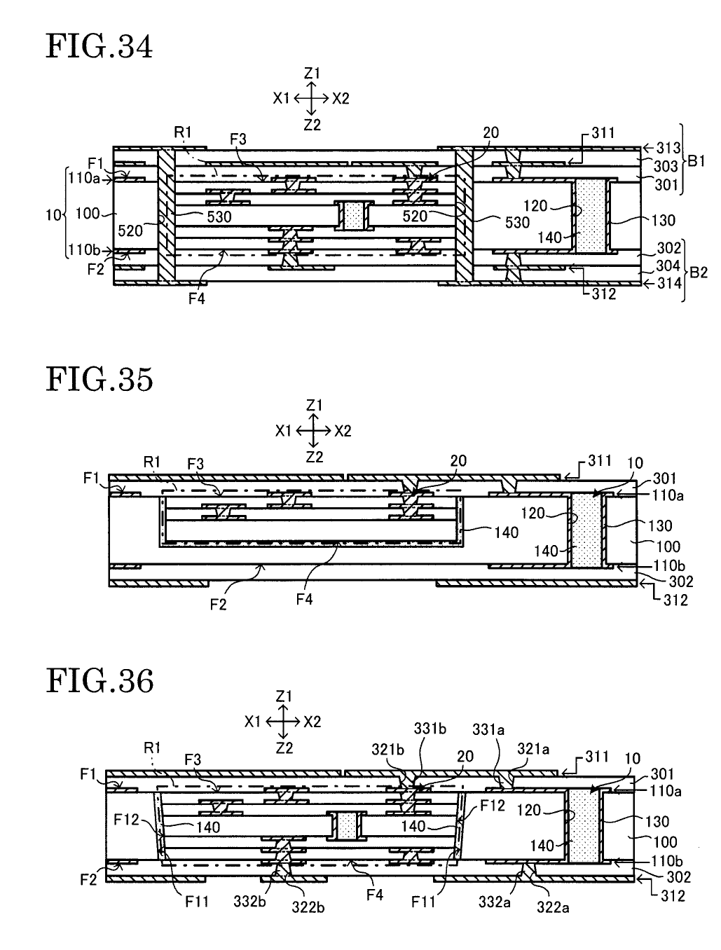

As shown in FIG. 34, on wiring board 10 (first rigid wiring board) and wiring board 20 (second rigid wiring board), a wiring board may have laminated section (B1) where multiple insulation layers (301, 303) and multiple conductive layers (311, 313) are alternately laminated as well as laminated section (B2) where multiple insulation layers (302, 304) and multiple conductive layers (312, 314) are alternately laminated. In the example shown in FIG. 34, through hole 520 for through-hole conductor 530 (joint conductor) penetrates through laminated sections (B1, B2) as well as wiring boards (10, 20).

Accommodation section (R1) is not limited to a hole that penetrates through wiring board 10 (first rigid wiring board). For example, as shown in FIG. 35, it may be a hole that does not penetrate through wiring board 10. However, to manufacture wiring boards more easily, or to accommodate even further multilayered wiring board 20 in accommodation section (R1), accommodation section (R1) is preferred to be a hole that penetrates through wiring board 10. Alternatively, accommodation section (R1) may also be an opening portion such as a groove, notch, cut or the like.

Wall surface (F11) of accommodation section (R1) is not limited to being substantially perpendicular to main surfaces (FIG. 1), and it may be tapered as shown in FIG. 36, for example. In the example in FIG. 36, side surface (F12) of wiring board 20 tapers from first surface (F1) toward second surface (F2), and wall surface (F11) of accommodation section (R1) tapers from third surface (F3) toward fourth surface (F4). Side surface (F12) of wiring board 20 tapers corresponding to wall surface (F11) of accommodation section (R1) (side surface of wiring board 10).

Regarding other factors, structures of wiring boards (10, 20) and insulation layers formed as their upper layers, as well as type, performance, measurements, quality, shapes, number of layers, positioning and so forth of the elements of such structures, may be modified freely within a scope that does not deviate from the gist of the present invention.

Wiring boards (10, 20) may each be a wiring board with a built-in electronic component.

To improve strength or enhance heat dissipation, a metal sheet may be built into the core substrate of wiring board 10 or 20.

The method for connecting wiring board 10 and wiring board 20 is not limited specifically. For example, wire bonding, flip-chip connection or the like may be employed.

The number of buildup layers may be different on the upper and lower surfaces of a wiring board. However, to mitigate stress, it is considered preferable to form the same number of buildup layers on the upper and lower surfaces of a wiring board so that symmetry on the upper and lower surfaces is enhanced.

Wiring boards (10, 20) may each be a single-sided wiring board having conductor (conductive layer) only on either the upper or the lower surface of the core substrate.

The structure of each conductive layer is not limited to being a triple-layered structure of metal foil, electroless plated film and electrolytic plated film. For example, it may be a double-layered structure of metal foil and electroless plated film or electrolytic plated film. Also, the structure of each filled conductor is not limited to being a double-layered structure of electroless plated film and electrolytic plated film. For example, it may be a single-layered structure only of electroless plated film or electrolytic plated film. If electroless plated film is omitted, a decrease in the adhesiveness between an insulation layer and a conductive layer may become a concern. Thus, surface treatment is preferred to be conducted on the insulation layer to enhance adhesiveness if required.

Each via conductor is not limited to being a filled conductor, and may be a conformal conductor.

The contents and the order of the procedure in the above embodiment may be modified freely within a scope that does not deviate from the gist of the present invention. Also, some step may be omitted depending on usage requirements or the like.

For example, the method for forming each conductive layer may be determined freely. Conductive layers may be formed by any one of the following methods or a combination of two or more of them: panel plating, pattern plating, full-additive, semi-additive (SAP), subtractive, transfer and tenting methods.

For example, conductive layers are formed by a subtractive method (a method for patterning through etching) in the above embodiment. However, a semi-additive (SAP) method may be used instead of a subtractive method. In a semi-additive method, after the entire surface of an insulative substrate is made conductive using electroless plated film (panel plating), resist is formed and electrolytic plating is formed where the resist is not present. Then, after the resist is removed, electroless plated film is patterned by etching.

Also, forming each insulation layer (interlayer insulation layer) is not limited to any specific method. For example, liquid or film-type thermosetting resins or their composite, or RCF (resin-coated copper foil) or the like may also be used instead of prepreg.

For example, wet or dry etching process may be employed instead of using a laser. When an etching process is employed, it is preferred to protect in advance with resist or the like portions that are not required to be removed.

The embodiment and modified examples above may be combined freely. For example, any structure shown in FIGS. 28A˜28C may be applied to any structure shown in FIGS. 29A˜36. It is preferred to select an appropriate combination according to usage requirements or the like.

A wiring board according to an embodiment of the present invention has a first rigid wiring board having an accommodation section, a second rigid wiring board accommodated in the accommodation section, and an insulation layer formed on the first rigid wiring board and on the second rigid wiring board. In such a wiring board, a conductor in the first rigid wiring board and a conductor in the second rigid wiring board are electrically connected to each other, a concavo-convex shape is formed on a side surface of the second rigid wiring board and on a wall surface of the accommodation section, and multiple convex portions formed on either the side surface of the second rigid wiring board or the wall surface of the accommodation section are inserted in a concave portion formed on the other.

A wiring board according to another embodiment of the present invention has a first rigid wiring board having an accommodation section, a second rigid wiring board accommodated in the accommodation section, and an insulation layer formed on the first rigid wiring board and on the second rigid wiring board. In such a wiring board, a conductor in the first rigid wiring board and a conductor in the second rigid wiring board are electrically connected to each other, a first concavo-convex shape is formed on a side surface of the second rigid wiring board and on a wall surface of the accommodation section, a convex portion of the first concavo-convex shape formed on either the side surface of the second rigid wiring board or the wall surface of the accommodation section is inserted into a concave portion of the first concavo-convex shape formed on the other, and a second concavo-convex shape finer than the first concavo-convex shape is formed at least either in the concave portion or in the convex portion.

A method for manufacturing a wiring board according to yet another embodiment of the present invention includes the following: preparing a first rigid wiring board having an accommodation section; accommodating a second rigid wiring board in the accommodation section; forming an insulation layer on the first rigid wiring board and on the second rigid wiring board; electrically connecting a conductor in the first rigid wiring board and a conductor in the second rigid wiring board to each other; and forming a concavo-convex shape on a side surface of the second rigid wiring board and on a wall surface of the accommodation section in such a way that multiple convex portions on one side are inserted into a concave portion on the other side.

A method for manufacturing a wiring board according to still another embodiment of the present invention includes the following: preparing a first rigid wiring board having an accommodation section; accommodating a second rigid wiring board in the accommodation section; forming an insulation layer on the first rigid wiring board and on the second rigid wiring board; electrically connecting a conductor in the first rigid wiring board and a conductor in the second rigid wiring board to each other; forming a first concavo-convex shape on a side surface of the second rigid wiring board and on a wall surface of the accommodation section in such a way that a convex portion on one side is inserted into a concave portion on the other side; and forming a second concavo-convex shape finer than the first concavo-convex shape in at least either the concave portion or the convex portion.

Obviously, numerous modifications and variations of the present invention are possible in light of the above teachings. It is therefore to be understood that within the scope of the appended claims, the invention may be practiced otherwise than as specifically described herein.

What is claimed is:

1. A wiring board, comprising:
a first rigid wiring board having an accommodation portion and a conductor;
a second rigid wiring board accommodated in the accommodation portion and having a conductor electrically connected to the conductor in the first rigid wiring board; and
an insulation layer formed over the first rigid wiring board and the second rigid wiring board,
wherein the first rigid wiring board has a wall surface defining the accommodation portion and having a concavo-convex shaped portion, and the second rigid wiring board has a side surface facing against the wall surface of the first rigid wiring board and having a concavo-convex shaped portion such that the concavo-convex shaped portion of the side surface of the second rigid wiring board engages with the concavo-convex shaped portion of the wall surface of the first rigid wiring board.

2. The wiring board according to claim 1, wherein the concavo-convex shaped portion of the wall surface of the first rigid wiring board is formed by cutting, and the concavo-convex shaped portion of the side surface of the second rigid wiring board is formed by cutting.

3. The wiring board according to claim 1, wherein the concavo-convex shaped portion of the side surface of the second rigid wiring board has a plurality of convex portions inserted into a concave portion of the concavo-convex shaped portion of the wall surface of the first rigid wiring board.

4. The wiring board according to claim 1, wherein the concavo-convex shaped portion of the wall surface of the first rigid wiring board and the concavo-convex shaped portion of the side surface of the second rigid wiring board have a plurality of convex portions and a plurality of concave portions, and the plurality of convex portions has a length of space between the convex portions which is substantially a same as a length of each of the convex portions.

5. The wiring board according to claim 1, wherein the concavo-convex shaped portion of the wall surface of the first rigid wiring board and the concavo-convex shaped portion of the side surface of the second rigid wiring board have a plurality of convex portions and a plurality of concave portions, and the plurality of convex portions has a length of space between the convex portions which is shorter than a length of each of the convex portions.

6. The wiring board according to claim 1, wherein the concavo-convex shaped portion of the wall surface of the first rigid wiring board and the concavo-convex shaped portion of the side surface of the second rigid wiring board have a plurality of convex portions and a plurality of concave portions, and each of the concave portions is configured to receive two of the convex portions.

7. The wiring board according to claim 1, wherein the concavo-convex shaped portion of the wall surface of the first rigid wiring board and the concavo-convex shaped portion of the side surface of the second rigid wiring board are formed entirely along the side surface of the second rigid wiring board and the wall surface of the first rigid wiring board.

8. The wiring board according to claim 1, wherein the concavo-convex shaped portion of the side surface of the second rigid wiring board and the concavo-convex shaped portion of the wall surface of the first rigid wiring board are formed adjacent to a corner of the second rigid wiring board.

9. The wiring board according to claim 1, wherein the concavo-convex shaped portion of the side surface of the second rigid wiring board and the concavo-convex shaped portion of the wall surface of the first rigid wiring board are formed in a region along a side of the second rigid wiring board.

10. The wiring board according to claim 1, wherein the first rigid wiring board forms a core substrate of the wiring board.

11. The wiring board according to claim 1, further comprising:
a conductive layer formed on the insulation layer;
a second insulation layer formed over the first rigid wiring board and the second wiring board on an opposite side of the insulation layer; and
a second conductive layer formed on the second insulation layer,
wherein the accommodation portion of the first rigid wiring board penetrates through the first rigid wiring board.

12. The wiring board according to claim 1, wherein the concavo-convex shaped portion of the side surface of the second rigid wiring board and the concavo-convex shaped portion of the wall surface of the first rigid wiring board has substantially a constant cycle of concave portions and convex portions.

13. The wiring board according to claim 12, wherein the constant cycle is set in a range of approximately 1 mm to approximately 3 mm, and the concavo-convex shaped portion of the side surface of the second rigid wiring board and the concavo-convex shaped portion of the wall surface of the first rigid wiring board has an amplitude which is set in a range of approximately 0.2 mm to approximately 1 mm.

14. The wiring board according to claim 1, wherein the side surface of the second rigid wiring board and the wall surface of the first rigid wiring board form a gap in which a resin is filled.

15. The wiring board according to claim 1, wherein the conductor of the first rigid wiring board and the conductor of the second rigid wiring board are electrically connected to each other by a plurality of via conductors formed in the insulation layer.

16. The wiring board according to claim 1, wherein the first rigid wiring board has a plurality of conductive layers which is less in number of layers than a plurality of conductive layers in the second rigid wiring board.

17. The wiring board according to claim 1, further comprising:
a first external connection terminal formed in a portion of the insulation layer directly above the first rigid wiring board; and
a second external connection terminal formed in a portion of the insulation layer directly above the second rigid wiring board.

18. The wiring board according to claim 1, further comprising a joint conductor formed in a hole extending through the first rigid wiring board and the second rigid wiring board such that the joint conductor connects the first rigid wiring board and the second rigid wiring board.

19. The wiring board according to claim 1, further comprising a planar conductive film formed directly on a boundary portion between the first rigid wiring board and the second rigid wiring board.

20. The wiring board according to claim 1, wherein the side surface of the second rigid wiring board is tapering from one surface of the second rigid wiring board toward an opposite surface of the second rigid wiring board, and the wall surface of the first rigid wiring board is tapering from one surface of the first rigid wiring board toward an opposite surface of the first rigid wiring board along the side surface of the second rigid wiring board.

21. The wiring board according to claim 1, wherein one of the concavo-convex shaped portion of the side surface of the second rigid wiring board and the concavo-convex shaped portion of the wall surface of the first rigid wiring board has second concavo-convex shaped portions finer than the concavo-convex shaped portions.

22. The wiring board according to claim 21, wherein the concavo-convex shaped portion of the wall surface of the first rigid wiring board has a convex portion and a concave portion, the concavo-convex shaped portion of the side surface of the second rigid wiring board has a convex portion and a concave portion, and the second concavo-convex shaped portions are formed in the concave portions and convex portions of the concavo-convex shaped portions of the wall surface of the first rigid wiring board and the side surface of the second rigid wiring board.

23. The wiring board according to claim 21, wherein the concavo-convex shaped portion of the wall surface of the first rigid wiring board has a convex portion and a concave portion, the concavo-convex shaped portion of the side surface of the second rigid wiring board has a convex portion and a concave portion, and the second concavo-convex shaped portions are formed in the convex portions of the concavo-convex shaped portions of the wall surface of the first rigid wiring board and the side surface of the second rigid wiring board.

24. The wiring board according to claim 21, wherein the concavo-convex shaped portion of the wall surface of the first rigid wiring board has a convex portion and a concave portion, the concavo-convex shaped portion of the side surface of the second rigid wiring board has a convex portion and a concave portion, and the second concavo-convex shaped portions are formed in the concave portions of the concavo-convex shaped portions of the wall surface of the first rigid wiring board and the side surface of the second rigid wiring board.

25. The wiring board according to claim 21, wherein the concavo-convex shaped portions have an amplitude which is in a range of approximately three times to approximately 15 times an amplitude of the second concavo-convex shaped portions.

26. The wiring board according to claim 21, wherein the first concavo-convex shaped portions have a width which is in a range of approximately three times to approximately 15 times a width of the second concavo-convex shaped portions.

27. A method for manufacturing a wiring board, comprising:
preparing a first rigid wiring board having an accommodation portion and a conductor;
preparing a second rigid wiring board having a conductor;
accommodating the second rigid wiring board in the accommodation portion of the first rigid wiring board;
forming an insulation layer over the first rigid wiring board and the second rigid wiring board; and
electrically connecting the conductor in the first rigid wiring board to the conductor in the second rigid wiring board,
wherein the preparing of the first rigid wiring board comprises forming a wall surface which defines the accommodation portion and has a concavo-convex shaped portion, the preparing of the second rigid wiring board comprises forming a side surface which faces against the wall surface of the first rigid wiring board and has a concavo-convex shaped portion such that the concavo-convex shaped portion of the side surface of the second rigid wiring board engages with the concavo-convex shaped portion of the wall surface of the first rigid wiring board, and the accommodating of the second rigid wiring board comprises engaging the concavo-convex shaped portion of the side surface of the second rigid wiring board with the concavo-convex shaped portion of the wall surface of the first rigid wiring board.

28. The method for manufacturing a wiring board according to claim 27, wherein the forming of the wall surface of the first rigid wiring board comprises cutting the first rigid wiring board such that the wall surface having the concavo-convex shaped portion is formed, and the forming of the side surface of the second rigid wiring board comprises cutting the second rigid wiring board such that the side surface having the concavo-convex shaped portion is formed.

29. The method for manufacturing a wiring board according to claim 28, wherein the cutting of the first rigid wiring board is conducted by a laser, and the cutting of the second rigid wiring board is conducted by a laser.

30. The method for manufacturing a wiring board according to claim 28, wherein the cutting of the first rigid wiring board is conducted by a die, and the cutting of the second rigid wiring board is conducted by a die.

31. The method for manufacturing a wiring board according to claim 27, further comprising forming second concavo-convex shaped portions which are finer than the concavo-convex shaped portions in at least one of a concave portion and a convex portion of the concavo-convex shaped portions.

32. The method for manufacturing a wiring board according to claim 27, wherein the concavo-convex shaped portion of the side surface of the second rigid wiring board is formed such that the concavo-convex shaped portion of the side surface of the second rigid wiring board has a plurality of convex portions inserted into a concave portion of the concavo-convex shaped portion of the wall surface of the first rigid wiring board.
